(19) United States
(12) Patent Application Publication
(10) Pub. No.: US 2024/0081109 A1
(43) Pub. Date: Mar. 7, 2024

(54) DISPLAY PANEL AND DISPLAY APPARATUS

(71) Applicants: Wuhan Tianma Micro-Electronics Co., Ltd., Wuhan (CN); Wuhan Tianma Micro-Electronics Co., Ltd, Shanghai Branch, Shanghai (CN)

(72) Inventors: Yu Xin, Wuhan (CN); Lin Zhang, Wuhan (CN); Xian Chen, Wuhan (CN)

(21) Appl. No.: 18/242,920

(22) Filed: Sep. 6, 2023

(30) Foreign Application Priority Data
Sep. 6, 2022 (CN) 202211085998.0

(51) Int. Cl. H10K 59/131

(52) U.S. Cl. CPC H10K 59/131

(57) ABSTRACT

A display panel and a display apparatus are provided in the present disclosure. The display panel includes a display region, a first non-display region and a second non-display region. The display region includes a plurality of first signal lines extending along the first direction; at least a part of the plurality of first signal lines includes at least one first line segment and at least one second line segment; the at least one first line segment is between two adjacent non-display regions; at least a part of the at least one second line segment is on a side of the first non-display region away from the second non-display region along the first direction; and/or, at least a part of the at least one second line segment is on a side of the second non-display region away from the first non-display region along the first direction.

### CROSS-REFERENCE TO RELATED APPLICATION

This application claims the priority of Chinese Patent Application No. 202211085998.0, filed on Sep. 6, 2022, the content of which is incorporated herein by reference in its entirety.

### TECHNICAL FIELD

The present disclosure generally relates to the field of display technology and, more particularly, relates to a display panel and a display apparatus.

### BACKGROUND

From CRT (cathode ray tube) displays to liquid crystal displays (LCDs), and to OLED (organic light-emitting diode) displays and LED (light-emitting diode) displays, the display industry has been experienced for decades of development. The display industry has been closely related to our lives, for example, from conventional mobile phones, tablets, TVs and PCs to current electronic devices such as smart wearable devices, VR, in-vehicle displays and the like.

In order to meet photosensitive needs of display products, such as capturing pictures, through holes may be normally formed in display products to displace photosensitive elements such as cameras. However, with the introduction of through holes, the wirings originally disposed in the display products may be disconnected by the through holes. In the existing technology, the connection of disconnected wirings may be normally realized by wiring around the through holes. Such manner may increase the width of a non-display region around the through holes, which may not be beneficial for realizing the narrow frame design around the through holes and may result in screen-to-body ratio reduction of the display products.

### SUMMARY

One aspect of the present disclosure provides a display panel. The display panel includes a display region and at least two non-display regions. The at least two non-display regions at least include a first non-display region and a second non-display region which are disposed to be adjacent to each other; the first non-display region and the second non-display region are arranged along a first direction; and the display region at least partially surrounds the at least two non-display regions. The display region includes a plurality of first signal lines extending along the first direction; at least a part of the plurality of first signal lines includes at least one first line segment and at least one second line segment; the at least one first line segment is between two adjacent non-display regions; at least a part of the at least one second line segment is on a side of the first non-display region away from the second non-display region along the first direction, and/or, at least a part of the at least one second line segment is on a side of the second non-display region away from the first non-display region along the first direction; and in a same first signal line, a first line segment of the at least one first line segment and a second line segment of the at least one second line segment are electrically connected with each other through a first crossing line.

Another aspect of the present disclosure provides a display apparatus including a display panel. The display panel includes a display region and at least two non-display regions. The at least two non-display regions at least include a first non-display region and a second non-display region which are disposed to be adjacent to each other; the first non-display region and the second non-display region are arranged along a first direction; and the display region at least partially surrounds the at least two non-display regions. The display region includes a plurality of first signal lines extending along the first direction; at least a part of the plurality of first signal lines includes at least one first line segment and at least one second line segment; the at least one first line segment is between two adjacent non-display regions; at least a part of the at least one second line segment is on a side of the first non-display region away from the second non-display region along the first direction, and/or, at least a part of the at least one second line segment is on a side of the second non-display region away from the first non-display region along the first direction; and in a same first signal line, a first line segment of the at least one first line segment and a second line segment of the at least one second line segment are electrically connected with each other through a first crossing line.

Other aspects of the present disclosure can be understood by those skilled in the art in light of the description, the claims, and the drawings of the present disclosure.

### BRIEF DESCRIPTION OF THE DRAWINGS

The accompanying drawings, which are incorporated into a part of the specification, illustrate embodiments of the present disclosure and together with the description to explain the principles of the present disclosure.

FIG. 1 illustrates a structural schematic of a display panel according to various embodiments of the present disclosure.

FIG. 2 illustrates another structural schematic of a display panel according to various embodiments of the present disclosure.

FIG. 3 illustrates a wiring schematic of first signal lines disposed by surrounding a first non-display region and a second non-display region.

FIG. 4 illustrates another structural schematic of a display panel according to various embodiments of the present disclosure.

FIG. 5 illustrates a schematic of a connection between pixel drive circuits and light-emitting elements in a display panel according to various embodiments of the present disclosure.

FIG. 6 illustrates another structural schematic of a display panel according to various embodiments of the present disclosure.

FIG. 7 illustrates a schematic of a connection between control lines and shift registers corresponding to the control lines in a pixel drive circuit.

FIG. 8 illustrates a schematic of a connection of fourth control lines corresponding to positions of a first non-display region and a second non-display region.

FIG. 9 illustrates a correspondence schematic between control lines and pixel rows in a display panel according to various embodiments of the present disclosure.

FIG. 10 illustrates a schematic of film layers of a display panel according to various embodiments of the present disclosure.

FIG. 11 illustrates a layout schematic between a first non-display region and a second non-display region in a display panel according to various embodiments of the present disclosure.

FIG. 12 illustrates a local enlarged view of a region A1 in FIG. 11.

FIG. 13 illustrates a local enlarged view of a region A2 in FIG. 12.

FIG. 14 illustrates another schematic of a connection of fourth control lines corresponding to positions of a first non-display region and a second non-display region.

FIG. 15 illustrates another schematic of a connection of fourth control lines corresponding to positions of a first non-display region and a second non-display region.

FIG. 16 illustrates another structural schematic of a display panel according to various embodiments of the present disclosure.

FIG. 17 illustrates a wiring schematic of first signal lines and second signal lines disposed by surrounding a first non-display region and a second non-display region.

FIG. 18 illustrates a panel layout schematic corresponding to a region A3 in FIG. 17.

FIG. 19 illustrates a panel layout schematic corresponding to a region A4 in FIG. 17.

FIG. 20 illustrates a panel layout schematic corresponding to a region A5 in FIG. 17.

FIG. 21 illustrates a wiring schematic of first signal lines and second signal lines disposed by surrounding a first non-display region and a second non-display region.

FIG. 22 illustrates a structural schematic of a display apparatus according to various embodiments of the present disclosure.

### DETAILED DESCRIPTION

Various exemplary embodiments of the present disclosure are described in detail with reference to accompanying drawings. It should be noted that unless specifically stated otherwise, relative arrangement of components and steps, numerical expressions and values described in these exemplary embodiments may not limit the scope of the present disclosure.

Following description of at least one exemplary embodiment may be merely illustrative and may not be configured to limit the present disclosure and its application or use.

The technologies, methods and apparatuses known to those skilled in the art may not be discussed in detail, but where appropriate, the technologies, methods and apparatuses should be regarded as a part of the present disclosure.

In all examples shown and discussed herein, any specific value should be interpreted as merely exemplary, rather than as a limitation. Therefore, other examples in exemplary embodiment may have different values.

It is obvious to those skilled in the art that various modifications and variations may be made in the present disclosure without departing from the spirit or scope of the present disclosure. Accordingly, the present disclosure may be intended to cover modifications and variations of the present disclosure that fall within the scope of corresponding claims (claimed technical solutions) and their equivalents. It should be noted that, implementation manners provided in exemplary embodiments of the present disclosure may be combined with each other if there is no contradiction.

It should be noted that similar reference numerals and letters may be configured to indicate similar items in following drawings. Therefore, once an item is defined in one drawing, it does not need to be further discussed in subsequent drawings.

In the existing technology, when through holes for placing photosensitive elements such as cameras are disposed in a display panel, the signal wirings originally disposed at the positions of the through holes may need to be wired around the through holes. When the number of signal wirings is large, the width of the frame around the through holes may be relatively large, which may not be beneficial for realizing the narrow frame design around the through holes and may result in screen-to-body ratio reduction of the display products.

The present disclosure provides a display panel. The display panel may include a display region and at least two non-display regions; the non-display regions may at least include the first non-display region and the second non-display region which are arranged to be adjacent to each other; the first non-display region and the second non-display region may be arranged along the first direction, and the display region may at least partially surround the non-display regions; the display region may include a plurality of first signal lines extending along the first direction; at least a part of the first signal lines may include a first line segment and at least one second line segment; the first line segment may be between two adjacent non-display regions; at least a part of the second line segments may be on the side of the first non-display region away from the second non-display region along the first direction; and/or at least a part of the second line segments may be on the side of the second non-display region away from the first non-display region along the first direction; and in a same first signal line, the first line segment and the second line segment may be electrically connected through the first crossing line. The electrical connection between the first line segment and the second line segment in the first signal line may be realized by introducing the first crossing line, which is beneficial for avoiding wiring around the first non-display region and the second non-display region. Therefore, the space to be compressed may be provided for the frame region corresponding to the first non-display region and the second non-display region, which is beneficial for realizing the narrow frame corresponding to the first non-display region and the second non-display region and increasing the screen-to-body ratio of the display panel and the display apparatus.

The technical solutions in embodiments of the present disclosure are clearly and completely described below with reference to accompanying drawings in embodiments of the present disclosure. Based on embodiments of the present disclosure, all other embodiments obtained by those of ordinary skill in the art without creative work fall within the protection scope of embodiments of the present disclosure.

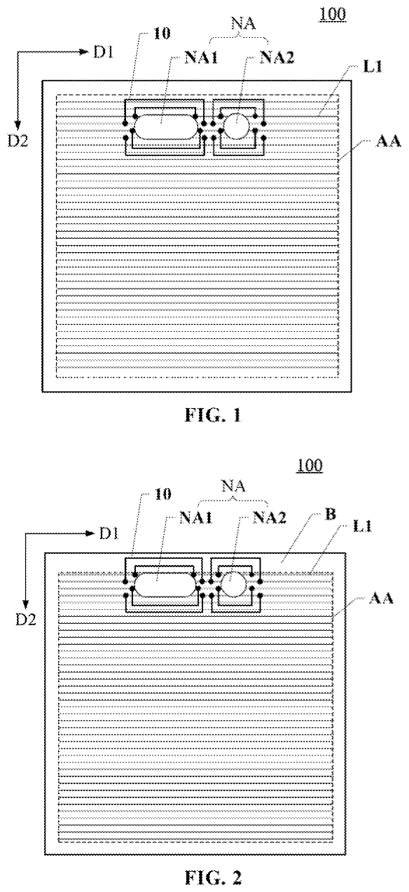

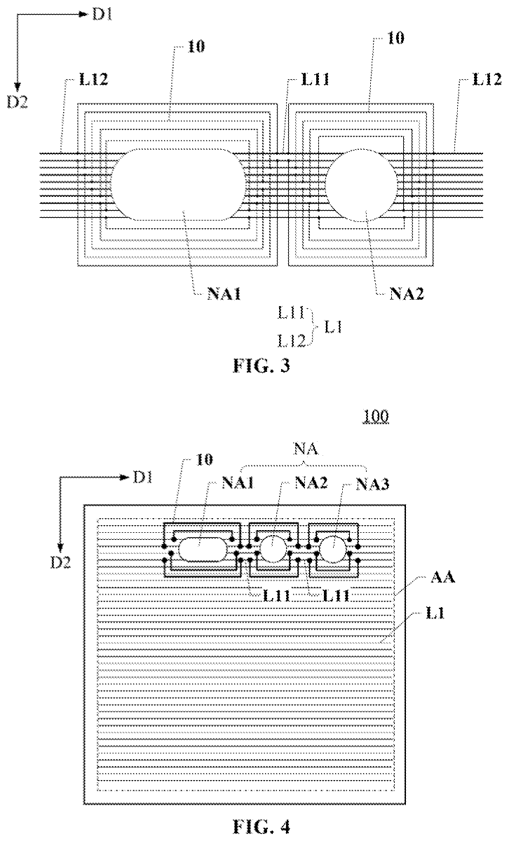

FIG. 1 illustrates a structural schematic of a display panel according to various embodiments of the present disclosure. FIG. 2 illustrates another structural schematic of a display panel according to various embodiments of the present disclosure. FIG. 3 illustrates a wiring schematic of first signal lines L1 disposed by surrounding the first non-display region NA1 and the second non-display region NA2. FIG. 1 illustrates a solution that a display region AA completely surrounds the first non-display region NA1 and the second non-display region NA2. FIG. 2 illustrates a solution that the display region AA half surrounds the first display region NA1 and the second display region NA2.

Referring to FIGS. 1 to 3, a display panel 100 provided by embodiments of the present disclosure may include the display region AA and at least two non-display regions NA. The non-display regions NA may include at least the first non-display region NA1 and the second non-display region NA2 which are arranged to be adjacent with each other. The first non-display region NA1 and the second non-display region NA2 may be arranged along the first direction D1; and the display region AA may at least partially surround the first non-display region NA1 and the second non-display region NA2.

The display region AA may include a plurality of first signal lines L1 extending along the first direction D1. At least a part of the first signal lines L1 may include a first line segment L11 and at least one second line segment L12. The first line segment L11 may be between two adjacent non-display regions NA. At least a part of the second line segments L12 may be on the side of the first non-display region NA1 away from the second non-display region NA2 along the first direction D1; and/or at least a part of the second line segments L12 may be on the side of the second non-display region NA2 away from the first non-display region NA1 along the first direction D1. In a same first signal line L1, the first line segment L11 and the second line segment L12 may be electrically connected through the first crossing line 10. In one embodiment, the first crossing line 10 and the first signal line L1 may be disposed in different layers.

Optionally, when the display panel provided by embodiments of the present disclosure is applied to a display apparatus, the first non-display region NA1 and the second non-display region NA2 may include optical device regions for placing optical devices such as cameras; and during the image capture phase, the optical device region may be configured to transmit light.

For example, referring to FIGS. 1-3, the display panel provided by embodiments of the present disclosure may be disposed with at least two non-display regions NA, and the display region AA may at least partially surround above-mentioned non-display regions NA. The non-display regions NA may at least include the first non-display region NA1 and the second non-display region NA2 arranged along the first direction D1. The display region AA may include the plurality of first signal lines L1 extending along the first direction D1. Along the first direction D1, a part of the first signal lines L1 may be overlapped with the first non-display region NA1 and the second non-display region NA2. Such part of the first signal lines L1 may include a first line segment L11 and at least one second line segment L12. The first line segment L11 may be between two adjacent non-display regions NA. At least a part of the second line segments L12 may be on the side of the first non-display region NA1 away from the second non-display region NA2, and/or at least a part of the second line segments L12 may be on the side of the second non-display region NA2 away from the first non-display region NA1. FIGS. 1-3 illustrate the solution that the display panel may include only the first non-display region NA1 and the second non-display region NA2; and the second line segments L12 may be disposed on the side of the first non-display region NA1 away from the second non-display region NA2 and on the side of the second non-display region NA2 away from the first non-display region NA1. In order to realize the electrical connection between the first line segment L11 and the second line segment L12 in the first signal line L1, the present disclosure introduces the first crossing line 10 into the display panel. In an implementation manner, the first crossing line 10 may be disposed in different layers from the first line segment L11 and the second line segment L12 in the first signal line L1. When the first line segment L11 and the second line segment L12 are connected through the first crossing line 10, there is no need to wire the frame region of the first non-display region NA1 or the second non-display region NA2, which may reduce the number of wirings corresponding to the frame regions of the first non-display region NA1 and the second non-display region NA2 and provide compression space for the frames of the first non-display region NA1 and the second non-display region NA2, thereby being beneficial for realizing the narrow frame design around the through holes corresponding to the first non-display region NA1 and the second non-display region NA2 and for increasing the screen-to-body ratio of the display panel and the display apparatus.

It should be noted that, FIGS. 1-2 in one embodiment may only illustrate the structure of the display panel. In an implementation, the structure of the display panel may include, but may not be limited to, such structure, and may also include other structures, such as the film layer structure, the pixel circuit, the drive circuit and the like of the display panel, which may not be described in detail herein, and may refer to the structure of the display panel in the existing technology. In addition, FIGS. 1-2 may only take a rectangular-shaped display panel as an example to describe in one embodiment. In some other embodiments of the present disclosure, the shape of the display panel may also be embodied in other shapes, such as a rounded rectangle, a circle, an ellipse, or any other feasible shape. In one embodiment, the number of the first signal lines L1 that are overlapped with the first display region AA and the second non-display region NA2 along the first direction D1 may be only for illustration and may not represent actual number.

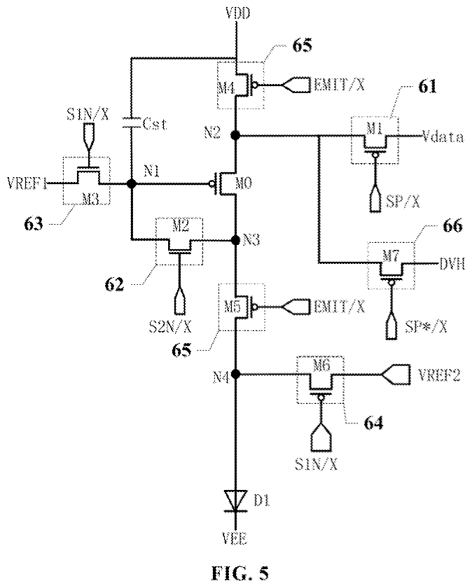

In addition, FIG. 1 may only take the display panel including two non-display regions NA as an example for description. In some other embodiments of the present disclosure, the number of non-display regions NA included in the display panel may also be three or more. For example, referring to FIG. 4. FIG. 4 illustrates another structural schematic of a display panel according to various embodiments of the present disclosure. When the display panel includes three non-display regions NA (for example, the first non-display region NA1, the second non-display region NA2, and the third non-display region NA3), the three non-display regions NA may be arranged along the first direction D1, and the first line segment L11 may be disposed between any two adjacent non-display regions NA.

Optionally, the display panel provided in one embodiment may be a display panel using an organic light-emitting diode display technology, that is, an OLED display panel. The basic structure of the light-emitting layer of the OLED display panel may normally include an anode, a layer of light-emitting material, and a cathode. When a suitable voltage is supplied from a power source, holes from the anode and electrons from the cathode may combine in the layer of light-emitting material to generate bright light. Compared with the thin film field effect transistor liquid crystal display, the OLED display apparatus may have the characteristics of high visibility, high brightness, high power-saving, light weight and thin thickness. Obviously, in some other embodiments of the present disclosure, the display panel may also be a display panel using inorganic light-emitting diode display technology, such as a Micro LED display panel, a Mini LED display panel, or the like.

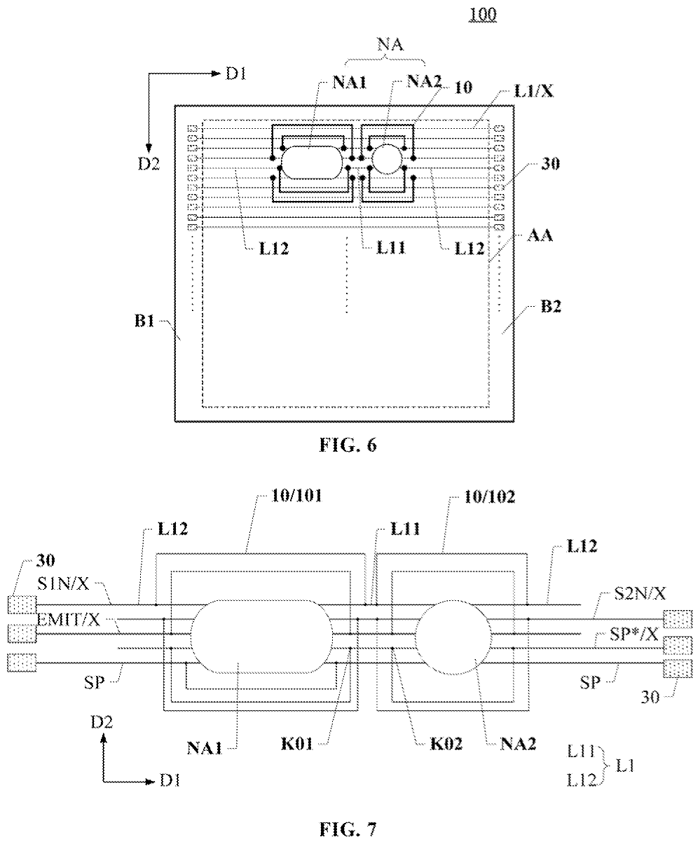

FIG. 5 illustrates a schematic of a connection between pixel drive circuits and light-emitting elements in a display panel according to various embodiments of the present disclosure. FIG. 6 illustrates another structural schematic of a display panel according to various embodiments of the present disclosure. Referring to FIGS. 5-6, in an optional embodiment of the present disclosure, the display panel may include a plurality of pixel drive circuits in the display region AA and light-emitting elements electrically connected to the pixel drive circuits. The pixel drive circuit may be electrically connected to a plurality of control lines X, and the first signal lines L1 may include the control lines X.

The display panel 100 may include the first frame region B1 and the second frame region B2 which are opposite along the first direction D1. Both the first frame region B1 and the second frame region B2 may include a plurality of shift registers 30. At least a part of the control lines X may be electrically connected to the shift register 30 in the first frame region B1, and at least a part of the control lines X may be electrically connected to the shift register 30 in the second frame region B2. The first crossing lines 10 corresponding to at least a part of the control lines X may be wired from the first non-display region NA1 and the second non-display region NA2 along the first side of the second direction D2; and the first crossing lines 10 corresponding to at least a part of the control lines X may be wired from the first non-display region NA1 and the second non-display region NA2 along the second side of the second direction D2. The first side and the second side may be opposite to each other along the second direction D2 which intersects the first direction D1.

It should be noted that FIG. 5 only illustrates the structure of one pixel drive circuit that is electrically connected to the light-emitting element. For example, the pixel drive circuit with 8T1C (eight transistors and one capacitor) structure may be configured as an example for illustration, which may not limit actual structure of the pixel drive circuit. In some other embodiments of the present disclosure, the pixel drive circuit may also be embodied in a 7T1C structure, which may not be limited in the present disclosure. Taking one embodiment shown in FIG. 5 as an example, the pixel drive circuit may include one drive transistor M0 and eight switch transistors M0-M7. In addition to the drive transistor M0, the rest of the transistors may be switch transistors. The gate electrode of the switch transistor may be electrically connected to the control line X, and a drive signal may be provided to the switch transistor through the control line X to control the switch transistor to be in conduction or cutoff. Optionally, the control lines X connected to the switch transistors may all be wired along the display panel in a manner of extending along the first direction D1. When the control line X is overlapped with the first non-display region NA1 and the second non-display region NA2 along the first direction D1, the control line X may form the first line segment L11 between the first non-display region NA1 and the second non-display region NA2 and form the second line segment L12 on the side of the first non-display region NA1 or the second non-display region NA2 away from the first line segment L11. The first signal lines L1 mentioned in above embodiment may include such control lines X. The first line segment L11 and the second line segment L12 in the control line X may be electrically connected through the first crossing line 10, thereby avoiding the problem that the frame width of the first non-display region NA1 and the second non-display region NA2 is excessively large due to wiring around the first non-display region NA1 and the second non-display region NA2 when the number of the control lines X is relatively large.

Referring to FIG. 5, optionally, the control line X corresponding to the pixel drive circuit may be connected to the shift register 30 in the frame region of the display panel, and a control signal may be provided to the control line X through the shift register 30 to control conduction and cut-off of the switch transistor in the drive circuit. For example, the non-display region NA of the display panel may include the first frame region B1 and the second frame region B2 that are oppositely arranged along the first direction D1, and shift registers 30 may be disposed in both the first frame region B1 and the second frame region B2. In the plurality of control lines X corresponding to a same pixel drive circuit, a part of the control lines X may be electrically connected to the shift registers 30 in the first frame region B1, and another part of the control lines X may be electrically connected to the shift registers 30 in the second frame region B2. In such way, it is beneficial for avoiding the problem that the width of one side frame of the display panel is excessively large when the shift registers 30 are aggregated in a same frame region of the display panel, balancing the widths of the first frame region B1 and the second frame region B2 and improving overall aesthetics of the display panel.

In addition, referring to FIGS. 3, 5 and 6, in the plurality of control lines X corresponding to the pixel drive circuit, the first crossing lines 10 corresponding to a part of control line X may be wired from the first side (for example, the upper side) of the first non-display region NA1 and the second non-display region NA2 along the second direction D2; and the first crossing lines 10 corresponding to another part of the control lines X may be wired from the second side (for example, the lower side) of the first non-display region NA1 and the second display region AA along the second direction D2. In such way, the space on the upper and lower sides of the first non-display region NA1 and the second non-display region NA2 along the second direction D2 may be fully utilized, which is beneficial for even wiring of the first crossing lines 10 around the first non-display region NA1 and the second non-display region NA2.

It should be noted that when the lengths of the first crossing lines 10 on a same side of the first non-display region NA1 and the second non-display region NA2 are different, it may result in different loadings of the first signal lines L1 corresponding to the first crossing lines 10 with different lengths. In order to balance impedance difference between the first signal lines L1, the cross-sectional regions of the first crossing lines 10 with different lengths may be changed. For example, the cross-sectional region of the first crossing line 10 with a longer length may be configured to be smaller than the cross-sectional region of the first crossing line 10 with a shorter length. Or at least a part of the line segments in the first crossing lines 10 that are closer to the first non-display region NA1 and the second non-display region NA2 may be configured as zigzagged lines or curved lines, and the line segments in the first crossing lines 10 that are far from the first non-display region NA1 and the second non-display region NA2 may be configured as straight lines, which may make the lengths of different first crossing lines 10 to be similar to or same with each other and also beneficial for balancing the impedance difference between different first signal lines L1.

Referring to FIG. 3, in an optional implementation manner of the present disclosure, the number of first crossing lines 10 wiring of the first side of the first non-display region NA1 and the second non-display region NA2 along the second direction D2 may be same as the number of the first crossing line lines 10 of the second side of the first non-display region NA1 and the second non-display region NA2 along the second direction D2.

It should be noted that the numbers of the first crossing lines 10 above and below the first non-display region NA1 and the second non-display region NA2 are same mentioned in embodiments of the present disclosure, which may refer to be same within allowable range of error. For example, the condition of the present application may also be satisfied when the number of the first crossing lines 10 located above and below the first non-display region NA1 and the second non-display region NA2 differs by 1.

In the display panel provided by embodiments of the present disclosure, when the electrical connection between the first line segments L11 and the second line segments L12 in the first signal lines L1 is realized by using the first crossing lines 10, the first crossing lines 10 may be wired from above or below the first non-display region NA1 and the second non-display region NA2 along the second direction D2, and the numbers of the first crossing lines 10 located above and below the first non-display region NA1 and the second non-display region NA2 may be defined to be approximately same. In such way, the first crossing lines 10 may be arranged as evenly as possible on the upper and lower sides of the first non-display region NA1 and the second non-display region NA2. On the one hand, surrounding space of the first non-display region NA1 and the second non-display region NA2 may be reasonably utilized; on the other hand, it is also beneficial for improving the mura phenomenon caused by uneven distribution of the first crossing lines 10 on the upper and lower sides of the first non-display region NA1 and the second non-display region NA2.

Referring to FIGS. 4-7, FIG. 7 illustrates a schematic of a connection between the control lines X and the shift registers 30 corresponding to the control lines 30 in a pixel drive circuit. In an optional embodiment of the present disclosure, the pixel drive circuit may include a data write module 61, a compensation module 62, a first reset module 63, a second reset module 64, a light-emitting control module 65 and a voltage adjustment module 66. The control lines X may include the first control line S1N connected to the control terminal of the first reset module 63, the second control line S2N connected to the control terminal of the compensation module 62, the third control line SP* connected to the control terminals of the second reset module 64 and the voltage adjustment module 66, the fourth control line SP connected to the control terminal of the data write module 61, and the light-emitting control line EMIT connected to the light-emitting control module 65.

Two of the first control line S1N, the second control line S2N, the third control line SP* and the light-emitting control line EMIT may be connected to the shift registers 30 in the first frame region B1, and the other two thereof may be connected to the shift registers 30 in the second frame region B2.

Optionally, the gate electrode of the drive transistor M0 may be connected to the first node N1, the source electrode of the drive transistor M0 may be connected to the second node N2, the drain electrode of the drive transistor M0 may be connected to the third node N3, and the light-emitting element may be coupled to the third node N3 through the fourth node N4. The first reset module 63 may be connected to the first node N1 to reset the first node N1; the second reset module 64 may be connected to the fourth node N4 to reset the fourth node N4; the data write module 61 and the voltage adjustment module 66 may be connected to the second node N2, and the voltage adjustment module 66 may be configured to regulate the threshold voltage of the drive transistor M0; and the compensation module 62 may be connected between the second node N2 and the third node N3. Optionally, the first reset module 63, the second reset module 64, the data write module 61, the compensation module 62 and the voltage adjustment module 66 may each include one transistor, but the number of transistors actually included in each module may not be limited in the present disclosure. In some other embodiments of the present disclosure, the number of transistors included in these modules may also be embodied as other numbers. In one embodiment, the control line X connected to the control terminals of the first reset module 63 and the second reset module 64 may be the first control line S1N, the control line X connected to the control terminal of the compensation module 62 may be the second control line S2N, the control line X connected to the control terminal of the voltage adjustment module 66 may be the third control line SP*, the control line X connected to the control terminal of the data write module 61 may be the fourth control line SP, and the control line X connected to the light-emitting control module 65 may be the light-emitting control line EMIT. Optionally, the first control line S1N, the second control line S2N, the third control line SP* and the light-emitting control line EMIT may all be unilaterally driven. That is, each of such control lines X may only be connected to a single shift register 30. For example, two of the first control line S1N, the second control line S2N, the third control line SP* and the light-emitting control line EMIT may be connected to the shift registers 30 in the first frame region B1; and the other two thereof may be connected to the shift registers 30 in the second frame region B2. In such way, in the region corresponding to the first non-display region NA1 and the second non-display region NA2, after being led out from the shift registers 30 in the first frame region B1 and extending to the left side of the first non-display region NA1, two of above four control lines X may be connected to the first line segment L11 between the first non-display region NA1 and the second non-display region NA2 through the first crossing line 10, and connected to the second line segment L12 on the right side of the second non-display region NA2 through the first crossing line 10. Therefore, in the first signal line L1, the second line segment L12 on the left side of the first non-display region NA1, the first line segment L11 between the first non-display region NA1 and the second non-display region NA2, and the second line segment L12 on the right side of the second non-display region NA2 may all receive signals transmitted by a same shift register 30, which may ensure normal display function of the sub-pixels connected to such line segments. Similarly, after being led out from the shift registers 30 in the second frame region B2, and extending to the right side of the second non-display region NA2, the other two of above four control lines may be connected to the first line segment L11 between the second non-display region NA2 and the first non-display region NA1 through the first crossing line 10, and connected to the second line segment L12 on the right side of the first non-display region NA1 through the first crossing line 10. Therefore, in the first signal line L1, the second line segment L12 on the right side of the second non-display region NA2, the first line segment L11 between the second non-display region NA2 and the first non-display region NA1, and the second line segment L12 on the left side of the first non-display region NA1 may all receive signals transmitted by a same shift register 30, which may ensure normal display function of the sub-pixels connected to these line segments.

When the first control line S1N, the second control line S2N, the third control line SP* and the light-emitting control line EMIT are all unilaterally driven, the shift registers 30 connected to such control lines X may be evenly distributed in the first frame region B1 and the second frame region B2, which may be beneficial for rationally utilizing the space of the first frame region B1 and the second frame region B2 and ensuring frame width consistency of the first frame region B1 and the second frame region B2.

FIG. 8 illustrates a schematic of a connection of fourth control lines SP corresponding to positions of the first non-display region NA1 and the second non-display region NA2. It should be noted that FIG. 8 only illustrates a part of the fourth control lines SP cut off by the first non-display region NA1 and the second non-display region NA2 and does not show other control lines cut off by the first non-display region NA1 and the second non-display region NA2.

Referring to FIGS. 4-7 and 8, in an optional implementation manner of the present disclosure, at least a part of the fourth control lines SP connected to the first crossing lines 10 may be connected to the shift registers 30 in the first frame region B1; and remaining fourth control lines SP connected to the first crossing lines 10 may be connected to the shift registers 30 in the second frame region B2.

For example, the control line X connected to the control terminal of the data write module 61 in the pixel drive circuit may be the fourth control line SP. Optionally, when the fourth control line SP is not overlapped with the first non-display region NA1 and the second non-display region NA2 along the first direction D1, such fourth control line SP may be bilaterally driven. That is, one terminal of the same fourth control line SP may be electrically connected to the shift register 30 in the first frame region B1; and the other terminal of the same fourth control line SP may be electrically connected to the shift register 30 in the second frame region B2, so that the drive capability of the fourth control line SP to the pixel drive circuit connected to the fourth control line SP may be improved.

Referring to FIG. 8, when the fourth control line SP is overlapped with the first non-display region NA1 and the second non-display region NA2 along the first direction D1, optionally, such fourth control line SP may use unilateral drive. That is, in the first line segment L11 corresponding to the fourth control line SP, a part of the first line segment L11 may be electrically connected to the second line segment L12 on the left side of the first non-display region NA1 only through the first crossing line 10 and further be electrically connected to the shift register 30 in the first frame region B1 through the second line segment L12. At this point, the shift register 30 in the first frame region B1 may be configured to provide signals to the second line segment L12 and the first line segment L11. Another part of the first line segment L11 may be electrically connected to the second line segment L12 on the right side of the second non-display region NA2 only through the first crossing line 10, and further be electrically connected to the shift register 30 in the second frame region B2 through the second line segment L12. At this point, the shift register 30 in the second frame region B2 may be configured to provide signals to the second line segment L12 and the first line segment L11. In such way, the number of shift registers 30 in the first frame region B1 and the second frame region B2 may not be increased, which may be beneficial for reducing the number of the first crossing line lines 10 in the display panel while ensuring the normal display of the sub-pixels at corresponding positions of the first line segment L11 and the second line segment L12, thereby simplifying the wiring complexity of the display panel.

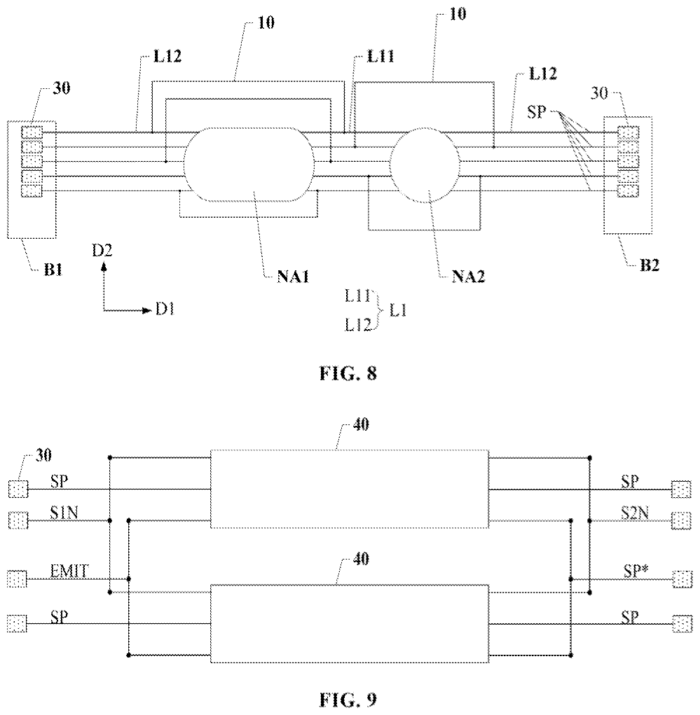

Referring to FIGS. 4-8 and 9, FIG. 9 illustrates a correspondence schematic between control lines X and pixel rows 40 in the display panel according to various embodiments of the present disclosure. In an optional embodiment of the present disclosure, a plurality of pixel rows 40 may be included, and each pixel row 40 may include a plurality of light-emitting elements; at least one of the first control line S1N, the second control line S2N, the third control line SP* and the light-emitting control line EMIT may be electrically connected to the pixel drive circuits corresponding to the light-emitting elements in the N pixel rows 40 respectively, where N2; and the fourth control line SP may be only electrically connected to the pixel drive circuits corresponding to the light-emitting elements in a same pixel row 40. It should be noted that in FIG. 9, the first control line S1N, the second control line S2N, the third control line SP* and the light-emitting control line EMIT may be electrically connected to the pixel drive circuits corresponding to the light-emitting elements in the two pixel rows 50, respectively, which may be taken as an example for illustration. That is, one above-mentioned control line may drive two pixel rows. In some other embodiments of the present disclosure, one above-mentioned control line may also drive three or more pixel rows, which may not be limited in the present disclosure. Referring to FIG. 9, a same shift register 30 may be connected to the first reset modules 63 in the pixel drive circuits of two pixel rows 40, and resetting the first nodes N1 of the pixel drive circuits in two pixel rows 40 may be realized through the control of the first control line S1N; a same shift register 30 may be connected to the second reset modules 64 in the pixel drive circuits of two pixel rows 40, and resetting the fourth nodes of the pixel drive circuits in two pixel rows 40 may be realized through the control of the first control line S1N; a same shift register 30 may be connected to the voltage adjustment modules 66 in the pixel drive circuits of two pixel rows 40, and the threshold compensation of the drive transistors of the pixel drive circuits in two pixel rows 40 may be realized through the control of the third control line SP*; and a same shift register 30 may be connected to the compensation modules 62 of the pixel drive circuits in two pixel rows 40, and threshold compensation in two pixel drive circuits may be realized through the control of the second control line S2N. In such way, it is equivalent to using a same shift register 30 to provide signals to the pixel drive circuits in two pixel rows 40. Compared with the manner that one shift register 30 only corresponds to the pixel drive circuits in one pixel row 40, the number of shift registers 30 included in the display panel may be greatly reduced since the space occupied by the shift registers 30 in the first frame region B1 and the second frame region B2 is reduced, thereby realizing narrow frame design of the display panel.

Referring to FIGS. 5-8, when the pixel drive circuit uses the 8T1C circuit shown in FIG. 5, optionally, a same first control line S1N may drive the pixel drive circuits corresponding to two pixel rows 40, a same light-emitting control line EMIT may drive the pixel drive circuits corresponding to two pixel rows 40, and the shift register 30 connected to the first control line S1N and the light-emitting control line EMIT may be in the first frame region B1; and a same second control line S2N may drive the pixel drive circuits corresponding to two pixel rows 40, a same third control line SP* may drive the pixel drive circuits corresponding to two pixel rows 40, and the shift register 30 connected to the second control line S2N and the fourth control line SP may be in the second frame region B2.

Referring to FIGS. 7 and 9, a same fourth control line SP may be only electrically connected to corresponding pixel drive circuits in a same pixel row 40. The region between the first non-display region NA1 and the second non-display region NA2 needs to be displayed. A same fourth control line SP may only need to be wired from one side. For example, a same fourth control line SP may be connected to the shift register 30 in the first frame region B1; after the fourth control line SP extends to the side of the first non-display region NA1 away from the second non-display region NA2, the fourth control line SP may be connected to the first line segment L11 between the first non-display region NA1 and the second non-display region NA2 through the first crossing line 10. Therefore, in the pixel row 40 overlapped with the first non-display region NA1 along the first direction D1, the pixel drive circuits of every two rows and one column may need six first crossing lines 10 at each of the upper and lower sides, respectively; and in the pixel row 40 overlapped with the second non-display region NA2 along the first direction D1, the pixel drive circuits of every two rows and one column may only need four first crossing lines 10 at each of the upper and lower sides. Assuming that the total number of pixel rows 40 overlapped with the first non-display region NA1 along the first direction D1 is N, the first crossing lines 10 corresponding to the first signal lines L1 in the pixel rows 40 may be in N/2 groups above and below the first non-display region NA1 and the second non-display region NA2, each group may be provided with six first crossing lines 10 at the position corresponding to the first non-display region NA1 (assuming that the line width of each first crossing line 10 is x, and the limit between two adjacent first crossing lines 10 is y, and x+y=D, such that the control space occupied by each group is 6D; optionally, X≤3 μm, Y≤3 μm, then D≤6 μm), four first crossing lines 10 may be disposed at the position corresponding to the second non-display region NA2, the number of first crossing lines 10 that need to be disposed at the upper and lower sides of the first non-display region may be 3N (N/2*6=3N for each of upper and lower sides), and the number of first crossing lines 10 that need to be disposed at the upper and lower sides of the second non-display region NA2 may be 2N (N/2*4=2N for each of upper and lower sides). Assuming that the distance between the first non-display region NA1 and the second non-display region NA2 along the first direction D1 is A, if the distance A≤5N*D, occupied frame space may be (5N*D−A)/2. Because the first line segment L11 at the position corresponding to the distance A is connected by the first crossing line 10, the proportion of occupied frame space may be greatly reduced. Conversely, if the distance A 5N*D, entire space between the first non-display region NA1 and the second non-display region NA2 may be used to complete the wiring of the first crossing lines 10, and there is no need to occupy the frame space of the first non-display region NA1 and the second non-display region NA2. The wiring space of the first crossing line 10 above or below the first non-display region NA1 may be N/2*6*D. Through such manner of connecting the first line segment L11 and the second line segment L12 with the U-shaped first crossing line 10, the frame space of 3N*D in the non-display region NA may be saved, which may be beneficial for realizing the narrow frame design of the non-display region NA and increasing the screen-to-body ratio of the display panel.

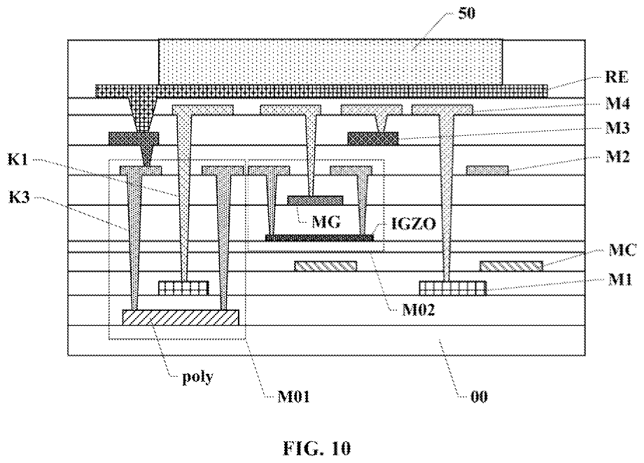

FIG. 10 illustrates a schematic of film layers of a display panel according to various embodiments of the present disclosure. It should be noted that FIG. 10 only illustrates a part of the film layers of the display panel and does not represent the number and size of the film layers actually included in the display panel. The display panel shown in embodiments of FIG. 10 illustrates two types of transistors. The first type transistor is a low temperature polysilicon transistor which includes an active layer poly; the second type transistor is a metal oxide transistor which includes an active layer IGZO (indium-gallium-zinc-oxide). Referring to FIG. 10, the display panel may be a multi-layer stack structure, including a metal layer, an active layer, an electrode layer, an insulating layer and the like, and further include an anode layer RE and a light-emitting layer 50 over the anode layer RE.

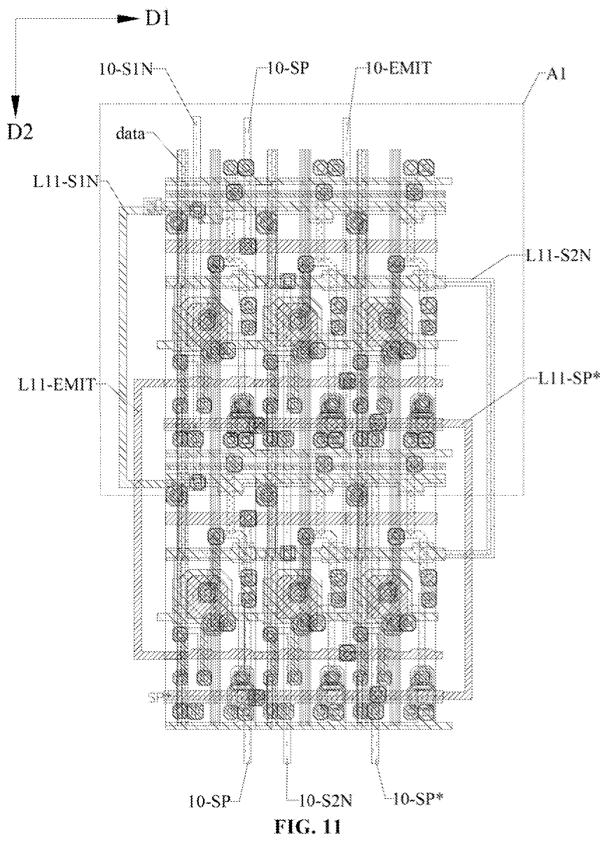

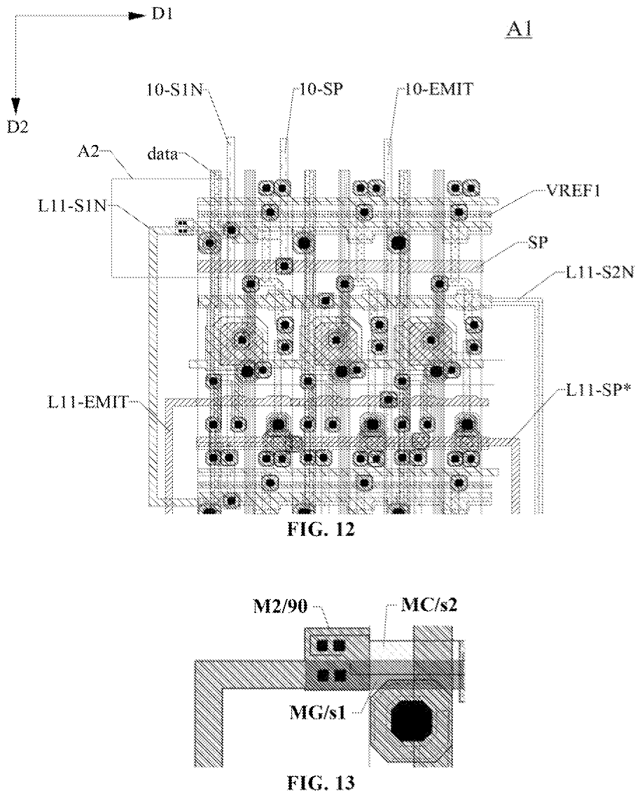

FIG. 11 illustrates a layout schematic between the first non-display region and the second non-display region in the display panel according to various embodiments of the present disclosure. FIG. 12 illustrates a local enlarged view of a region A1 in FIG. 11. One embodiment shown in FIG. 11 illustrates corresponding connection relationship of two pixel rows between the first non-display region and the second non-display region. The first crossing line 10-S1N may correspond to a part of the line segment extending along the second direction D2 in the first crossing line electrically connected to the first control line S1N; the first crossing line 10-SP may correspond to a part of the line segment extending along the second direction D2 in the first crossing line electrically connected to the fourth control line SP; the first crossing line 10-EMIT may correspond to a part of the line segment extending along the second direction D2 in the first crossing line electrically connected to the light-emitting control line EMIT; the first crossing line 10-S2N may correspond to a part of the line segment extending along the second direction D2 in the first crossing line electrically connected to the second control line S2N; the first crossing line 10-SP* may correspond to a part of the line segment extending along the second direction D2 in the first crossing line electrically connected to the third control line SP*; the first line segment L11-S1N may correspond to the first line segment corresponding to the first control line S1N; the first line segment L11-EMIT may correspond to the first line segment corresponding to the light-emitting control line; the first line segment L11-S2N may correspond to the first line segment corresponding to the second control line; and the first line segment L11-SP* may correspond to the first line segment corresponding to the third control line.

Referring to FIGS. 7, 11 and 12, in an optional embodiment of the present disclosure, the first line segment L11 may include a first terminal adjacent to the first non-display region NA1 and a second terminal adjacent to the second non-display region NA2; and the first or second terminals of N first line segments L11 corresponding to at least one of the first control line S1N, the second control line S2N, the third control line SP*, and the light-emitting control line EMTI in adjacent N pixel rows may be electrically connected.

In embodiments shown in FIGS. 11 and 12, taking the one-drive-two design in the pixel circuit as an example, in the two pixel rows between the first non-display region and the second non-display region, the first terminals of the first line segments corresponding to two adjacent first control lines S1N may be electrically connected; the first terminals of the first line segments corresponding to two adjacent light-emitting control lines EMIT may be electrically connected; the second terminals of the first line segments corresponding to two adjacent second control lines S2N may be electrically connected; and the second terminals of the first line segments corresponding to two adjacent third control lines SP* may be electrically connected. In some other embodiments of the present disclosure, the first terminals or the second terminals of above-mentioned control lines in three or more pixel rows may also be electrically connected to receive a same signal, which may not be limited in the present disclosure.

In such way, the control lines that are electrically connected to each other may only need to be connected to one shift register, and control signals may be provided to the control lines that are connected to each other through a same shift register, which may effectively reduce the number of shift registers actually included in the display panel, thereby being beneficial for reducing the frame.

FIG. 13 illustrates a local enlarged view of a region A2 in FIG. 12. FIG. 13 illustrates a connection relationship of two gate electrodes of the metal oxide transistor. Referring to FIGS. 5, 10 and 13, in an optional embodiment of the present disclosure, at least one of the first reset module 63 and the compensation module 62 may include a metal oxide transistor; between the first non-display region NA1 and the second non-display region NA2, along the thickness direction of the display panel, the metal oxide transistor may include an active layer IGZO, and a first gate electrode s1 and a second gate electrode s2 respectively which are on two sides of the active layer IGZO; and in a same metal oxide transistor, the terminals of the first gate electrode s1 and the second gate electrode s2 may be electrically connected with each other.

The metal oxide transistor may belong to the second type transistor M02. The first gate electrode s1 may be on the gate metal layer MG, the second gate electrode s2 may be on the capacitor metal layer MC, and the first gate electrode s1 and the second gate electrode s2 may be respectively on the upper and lower sides of the active layer IGZO. In embodiments of the present disclosure, the first gate electrode s1 and the second gate electrode s2 of the metal oxide transistor may be electrically connected between the first non-display region and the second non-display region, so that the first gate electrode s1 and the second gate electrode s2 of the metal oxide transistor may receive a same signal. In such way, the first gate electrode s1 and the second gate electrode s2 of a same metal oxide transistor may share a same control line, thereby being beneficial for reducing the leakage current of the metal oxide transistor and improving the stability of the device, and more beneficial for avoiding or reducing the influence of the leakage current of the metal oxide transistor on the first node. In addition, the second gate electrode s2 in the metal oxide transistor may also play a certain blocking role, which may avoid the influence of particles on the active layer IGZO in the metal oxide transistor. Connecting the first gate electrode s1 and the second gate electrode s2 may be also beneficial for improving the mobility of the device.

Optionally, the first gate electrode s1 and the second gate electrode s2 may be electrically connected through other conductive layers in the display panel. For example, referring to FIGS. 10 and 13, a connection part 90 on the second metal layer M2 may be provided. The first gate electrode s1 may be electrically connected to the connection part 90 through a punch hole, and the second gate electrode s2 may be electrically connected to the connection part 90 through a punch hole, such that the electrical connection between the first gate electrode s1 and the second gate electrode s2 may be realized. Obviously, the present application may not limit the film layer on which the connection part 90 is located and disposing the connection part 90 on the second metal layer M2 may be merely for illustration. In some other embodiments of the present disclosure, the connection part 90 may also be disposed on other film layers.

Referring to FIGS. 5-10, in an optional embodiment of the present disclosure, the first control line S1N, the second control line S2N, the third control line SP*, the fourth control line SP and the light-emitting control line EMIT may be distributed in at least two different film layers.

The film layer structure corresponding to one embodiment shown in FIG. 10 may include metal layers such as the first metal layer M1, the second metal layer M2, the third metal layer M3, the fourth metal layer M4, a capacitor metal layer MC, and a gate metal layer MG. Optionally, the first crossing line 10 in embodiments of the present disclosure may be disposed on the fourth metal layer M4, and above-mentioned control line X included in the first signal line L1 may be disposed on at least two metal layers among other metal layers.

The pixel drive circuits corresponding to the sub-pixels in the display panel may be respectively connected to the first control line S1N, the second control line S2N, the third control line SP*, the fourth control line SP and the light-emitting control line EMIT to obtain control signals, such that in the display panel, the first control line S1N, the second control line S2N, the third control line SP*, the fourth control line SP and the light-emitting control line EMIT may all extend along the first direction D1. When these control lines X are distributed on a same film layer, excessively small spacing between adjacent lines may cause signal interference. Therefore, it is beneficial for increasing the screen-to-body ratio of the display panel and increasing the distance between adjacent wirings to avoid signal interference between the wirings.

Referring to FIG. 7, in an optional embodiment of the present disclosure, the first crossing lines 10 corresponding to the first control line S1N, the second control line S2N, the third control line SP* and the light-emitting control line EMIT may respectively include the first sub-first-crossing-line 101 and the second sub-first-crossing-line 102; and for the first line segment L11 in each of the first control line S1N, the second control line S2N, the third control line SP*, and the light-emitting control line EMIT, the first terminal may be connected to the second line segment L12, on the side of the first non-display region NA1 away from the second non-display region NA2 along the first direction D1, through the first sub-first-crossing-line 10, and the second terminal may be connected to the second line segment L12, on the side of the second display region AA along the first direction D1 away from the first non-display region NA1, through the second sub-first-crossing-line 102.

Optionally, in the display panel provided by embodiments of the present disclosure, the first control line S1N, the second control line S2N, the third control line SP* and the light-emitting control line EMIT connected to the pixel drive circuits may be all unilaterally driven. That is, each of such control lines X may be connected to only one shift register 30. When such control lines X include the first line segment L11 between the first non-display region NA1 and the second non-display region NA2, the second line segment L12 on the side of the first non-display region NA1 away from the second non-display region NA2 and the second line segment L12 on the side of the second non-display region NA2 away from the first non-display region NA1, and when the first line segment L11 and two second line segments L12 all receive signals from a same shift register 30, the first sub-first-crossing-line 101 may be configured to electrically connect the first line segment L11 and the second line segment L12 on the left side of the first non-display region NA1, and the second sub-first-crossing-line 102 may be used to electrically connect the first line segment L11 and the second line segment L12 on the right side of the first non-display region NA1 in embodiments of the present disclosure. In such way, the first sub-first-crossing-line 101 and the second sub-first-crossing-line 102 may be configured to realize the electrical connection between the first line segment L11 and two second line segments L12, and the sub-pixels corresponding to the first line segment L11 and two second line segments L12 may all receive the signals sent by the shift registers 30, thereby being beneficial for ensuring normal display function of corresponding sub-pixels.

Referring to FIGS. 7, 11 and 12, in an optional embodiment of the present disclosure, at least three pixel columns may be disposed between the first non-display region NA1 and the second non-display region NA2; at least a part of the first line segments L11 may be electrically connected to one first crossing line 10 through the first via K01 and electrically connected to another first crossing line 10 through the second via K02; and along the first direction D1, the distance between the first via K01 and the second via K02 may be greater than or equal to total width of three consecutive pixel columns.

At least a part of the first line segments L11 disposed between the first non-display region NA1 and the second non-display region NA2 may need to be electrically connected to the second line segments L12 on two sides the first line segment through two first crossing lines 10, respectively. For example, in one embodiment shown in FIG. 7, such first line segments may be the first line segments L11 corresponding to the first control line S1N, the second control line S2N, the third control line SP* and the light-emitting control line EMIT. In one embodiment, the distance between the first via K01 and the second via K02 connected to a same first line segment L11 along the first direction D1 may be configured to be greater than or equal to total width of three continuous pixel columns between the first non-display region NA1 and the second non-display region NA2, which may be beneficial for ensuring the interval between the first via K01 and the second via K02, avoiding the phenomenon that the distance between the first via K01 and the second via K02 is excessively small to cause interference or short-circuit between two holes and reducing fabrication difficulty of the first via K01 and the second via K02.

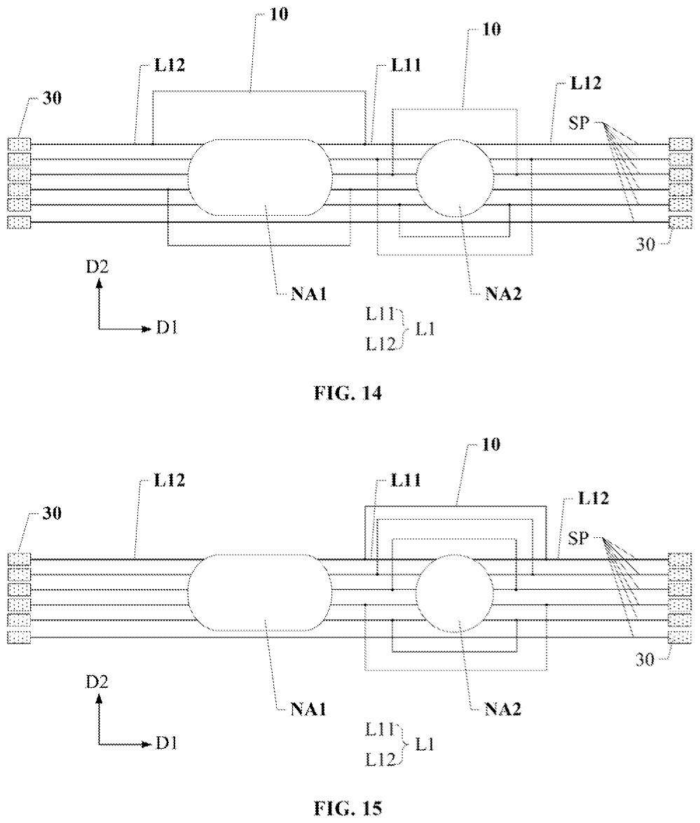

FIG. 14 illustrates another schematic of a connection of fourth control lines SP corresponding to positions of the first non-display region NA1 and the second non-display region NA2. It should be noted that FIG. 14 only illustrates a part of the fourth control lines SP cut off by the first non-display region NA1 and the second non-display region NA2 and does not show other control lines X cut off by the first non-display region NA1 and the second non-display region NA2.

Referring to FIG. 14, in an optional embodiment of the present disclosure, the first line segment L11 in the fourth control line SP may be electrically connected to the second line segment L12 on one side of the first line segment L11 along the first direction D1 through the first crossing line 10.

Optionally, in the display panel provided by embodiments of the present disclosure, in the fourth control line SP connected to the data write module 61 in the pixel drive circuit, the fourth control line SP that is not overlapped with the first non-display region NA1 and the second non-display region NA2 along the first direction D1 may be bilaterally driven, that is, two terminals of such part of the fourth control line SP may be respectively connected to different shift registers 30. In the fourth control line SP overlapped with the first non-display region NA1 and the second non-display region NA2 along the first direction D1, two control lines X may correspond to a same pixel row 40, and a same first line segment L11 may be electrically connected to the second line segment L12 on the left side of the first non-display region NA1 only through the first crossing line 10. At this point, the first line segment L11 may obtain a signal through the shift register 30 in the first frame region B1 that is electrically connected to the second line segment L12 on the left side of the first non-display region NA1, and the second line segment L12 on the right side of the second non-display region NA2 may not need to be electrically connected to the first line segment L11 and may obtain a control signal through the shift register 30 in the second frame region B2. Or a same first line segment L11 may be electrically connected to the second line segment L12 on the right side of the second non-display region NA2 only through the first crossing line 10. At this point, the first line segment L11 may obtain a control signal through the shift register 30 in the second frame region B2 that is electrically connected to the second line segment L12 on the right side of the second non-display region NA2, and the second line segment L12 on the left side of the first non-display region NA1 may not need to be electrically connected to the first line segment L11 and may obtain a control signal through the shift register 30 in the first frame region B1. The connection relationship between the fourth control line SP and the shift register 30 may reduce the number of the first crossing lines 10, thereby being beneficial for simplifying overall wiring difficulty of the display panel.

It should be noted that, in the fourth control line SP overlapped with the first non-display region NA1 and the second non-display region NA2 along the first direction D1, if corresponding first line segment L11 is only connected to one second line segment L12 through one first crossing line 10, above embodiment illustrates the case of the first crossing lines 10 arranged around the first non-display region NA1 and the second non-display region NA2. In some other embodiments of the present disclosure, the part of the first crossing lines 10 may be only arranged around the second non-display region NA2, for example, referring to FIG. 15. FIG. 15 illustrates another schematic of a connection of fourth control lines corresponding to positions of a first non-display region and a second non-display region. Obviously, in some other embodiments of the present disclosure, above-mentioned first crossing lines corresponding to the fourth control lines may also only be around the first non-display region, which may not be limited in the present disclosure.

Referring to FIGS. 7, 8, 11 and 12, in an optional embodiment of the present disclosure, in the first crossing lines 10 connected to the fourth control lines SP, at least a part of the first crossing lines 10 may be on the first side of the first line segment L11 along the second direction D2, and at least a part of the first crossing lines 10 may be on the second side of the first line segment L11 along the second direction D2; and in the first crossing lines 10 connected to at least one of the first control line S1N, the second control line S2N, the third control line SP* and the light-emitting control line EMIT, at least a part of the first crossing lines 10 may be on at least one side of the first line segment L11 along the second direction D2.

For example, due to the limited space between the first non-display region NA1 and the second non-display region NA2, when the first line segments L11 in the first non-display region NA1 and the second non-display region NA2 are electrically connected to the second line segments L12 through the first crossing lines 10, at least part of the line segments of the first crossing lines 10 must be led out from the region between the first non-display region NA1 and the second non-display region NA2. In embodiments of the present disclosure, it configures that in the first crossing lines 10 connected to the fourth control lines SP, a part of the first crossing lines 10 may be disposed above the first line segments L11, another part of the first crossing lines 10 may be arranged below the first line segments L11; and in the crossing lines connected to other control lines, at least a part of the first crossing lines 10 may be on at least one side of the first line segment L11 along the second direction. In such way, the first crossing lines 10 around the first non-display region NA1 and the second non-display region NA2 may be distributed as evenly as possible above and below the first line segments L11. On the one hand, surrounding space of the first non-display region NA1 and the second non-display region NA2 may be reasonably utilized; on the other hand, it is also beneficial for improving the screen mura phenomenon caused by uneven distribution of the first crossing lines 10 on the upper and lower sides of the first non-display region NA1 and the second non-display region NA2.

Referring to FIGS. 7, 11 and 12, in an optional embodiment of the present disclosure, at least three pixel columns may be disposed between the first non-display region NA1 and the second non-display region NA2; in the first crossing line lines 10, which are between the first non-display region NA1 and the second non-display region NA2 and correspond to the first control line S1N, the second control line S2N, the third control line SP*, the fourth control line SP and the light-emitting control line EMIT, the line segments extending along the second direction D2 may be within a range defined by three consecutive pixel columns. Such arrangement is beneficial for rationally utilizing the space between the first non-display region NA1 and the second non-display region NA2 and avoiding the phenomenon of occupying the frame space of the first non-display region NA1 or the second non-display region NA2 due to excessively large space occupied by the line segments extending along the second direction D2, thereby being beneficial for reducing the frame width of the first non-display region NA2 and the second non-display region NA2.

Referring to FIG. 2, in an optional embodiment of the present disclosure, the display panel 100 may further include a frame region B disposed at least partially around the display region AA.

For example, one embodiment shown in FIG. 2 is described by taking the first non-display region NA1 and the second non-display region NA2 adjacent to the upper frame region of the display panel as an example. When the first non-display region NA1 and the second non-display region NA2 are adjacent to the upper frame of the display panel, in the first crossing lines 10 connecting the first line segments L11 and the second line segments L12 in the first signal lines L1, at least a part of the first crossing lines 10 may be wired from above the first non-display region NA1 and the second non-display region NA2. In one embodiment, at least a part of the line segments in such part of the first crossing lines 10 may be arranged in the upper frame region B. In such way, the overlapping area between the first crossing line 10 and the display region AA may be reduced, which is beneficial for reducing caused coupling interference when the first crossing lines 10 are overlapped with other wirings in the display region AA, thereby being beneficial for improving the accuracy and stability of the signal transmitted on the first crossing line 10.

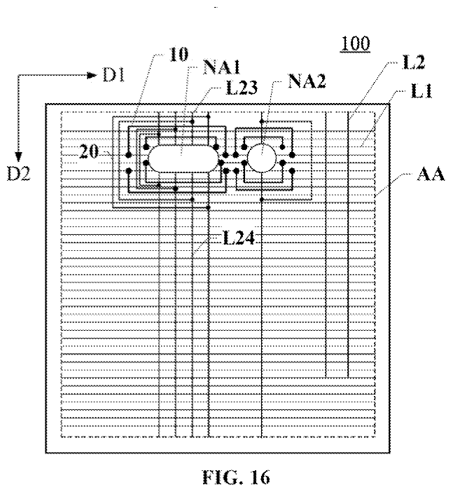

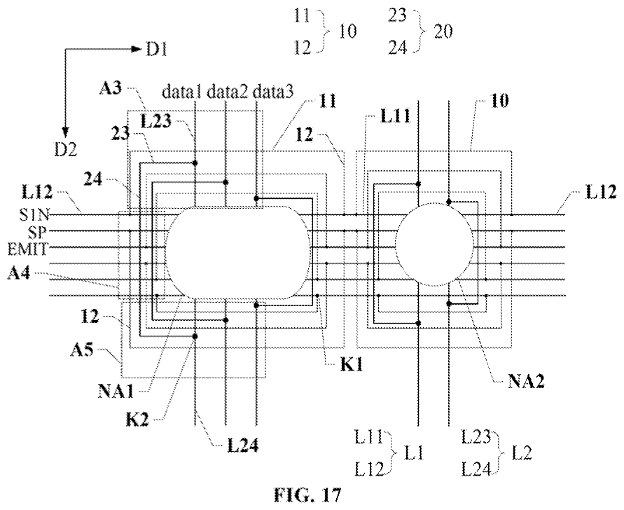

FIG. 16 illustrates another structural schematic of a display panel according to various embodiments of the present disclosure. FIG. 17 illustrates a wiring schematic of first signal lines L1 and second signal lines L2 disposed by surrounding the first non-display region NA1 and the second non-display region NA2. In one embodiment, the solution that the display panel includes the second signal line L2 extending along the second direction D2 is described.

Referring to FIGS. 16-17, in an optional embodiment of the present disclosure, the display region AA may further include a plurality of second signal lines L2 extending along the second direction D2; at least a part of the second signal lines L2 may include a third line segment L23 and a fourth line segment L24 arranged along the second direction D2; along the second direction D2, the third line segment L23 and the fourth line segment L24 may be on two sides of the first non-display region NA1 or on two sides of the second non-display region NA2; in a same second signal line L2, the third line segment L23 and the fourth line segment L24 may be electrically connected through the second crossing line 20; and at least a part of the second crossing lines 20 may be disposed on a same layer as the first crossing lines 10, and the second direction D2 may intersect with the first direction D1.

For example, when the first non-display region NA1 and the second non-display region NA2 are introduced into the display panel 100, in the second signal lines L2 extending along the second direction D2 in the display panel 100, at least a part of the second signal lines L2 may be overlapped with the first non-display region NA1 or the second non-display region NA2 along the second direction D2; and such part of the second signal lines L2 may include the third line segment L23 and the fourth line segment L24 located on two sides of the non-display region NA along the second direction D2, respectively. The third line segment L23 and the fourth line segment L24 in a same second signal line L2 may be electrically connected through the second crossing line 20. Optionally, the second crossing line 20 and the second signal line L2 may be disposed at different layers, and at least a part of the second crossing lines 20 may be disposed at a same layer as the first crossing line 10. The third line segment L23 and the fourth line segment L24 in the second signal line L2 may be connected by the second crossing line 20 disposed at a different layer from the second signal line L2, and there is no need for wiring at the frame region of the first non-display region NA1 or the second non-display region. Therefore, the number of wirings corresponding to the frame regions of the first non-display region NA1 and the second non-display region NA2 may also be reduced, and compression space may be provided for the frames of the first non-display region NA1 and the second non-display region NA2, which may be beneficial for realizing the narrow frame design around the through holes corresponding to the first non-display region NA1 and the second non-display region NA2 and increasing the screen-to-body ratio of the display panel.

Referring to FIG. 16 and FIG. 17, in an optional embodiment of the present disclosure, the first crossing line 10 and the second crossing line 20 may be disposed at a same layer.

When the first crossing line 10 connecting the first line segment L11 and the second line segment L12 and the second crossing line 20 connecting the third line segment L23 and the fourth line segment L24 are simultaneously introduced into the display panel and disposed at a same layer, which is equivalent to adding a single film layer in the display panel to configure the first crossing line 10 and the second crossing line 20, there is no need to introduce different film layer structures for the first crossing line 10 and the second crossing line 20, respectively. Therefore, while reducing the frame width of the non-display region NA such as the first non-display region NA1 and the second non-display region NA2 in the display panel by using the first crossing line 10 and the second crossing line 20, it may be also beneficial for simplifying overall film layer complexity of the display panel.

Referring to FIG. 10 and FIG. 17, in an optional embodiment of the present disclosure, the first crossing line 10 may be connected to the first signal line L1 through the first connection hole K1, and the second crossing line 20 may be electrically connected to the second signal line L2 through the second connection hole K2; and the display panel may further include a plurality of third connection holes K3. Along the thickness direction of the display panel, the first connection holes K1, the second connection holes K2 and the third connection holes K3 may not be overlapped with each other.

It should be noted that, in order to control normal display of the display panel, a drive layer may be normally disposed in the display panel and may be a multi-layer stacked structure. When the structures in two different film layers need to be electrically connected with each other, a connection hole may be normally formed in an insulating layer between two film layers, and the electrical connection between two film layers may be realized through the connection hole. For example, the anode of the light-emitting element may be electrically connected to the transistor on the drive layer through the connection hole, and it is assumed that such part of the connection hole is the third connection hole K3.

When the first crossing line 10 connecting the first line segment L11 and the second line segment L12 is introduced into the display panel, the first crossing line 10 may be disposed at different layers from the first line segment L11 and the second line segment L12. At this point, the first crossing line 10 may be electrically connected to the first line segment L11 and the second line segment L12 through the first connection hole K1. When the second crossing line 20 connecting the third line segment L23 and the fourth line segment L24 is introduced into the display panel, the second crossing line 20 may be disposed at different layers from the third line segment L23 and the fourth line segment L24. At this point, the second crossing line 20 may be electrically connected to the third line segment L23 and the fourth line segment L24 through the second connection hole K2. When the first crossing line 10 and the second crossing line 20 are introduced, the first connection hole K1 and the second connection hole K2 in embodiments of the present application may be equivalent to newly added connection holes based on existing third connection hole K3 in the display panel. At this point, embodiments of the present disclosure defines that the first connection hole K1, the second connection hole K2 and the third connection hole K3 may not be overlapped along the thickness direction of the display panel. That is, the first connection hole K1, the second connection hole K2 and the third connection hole K3 in the display panel may be disposed to be staggered and may not interfere with each other. Therefore, the introduction of the first connection hole K1 and the second connection hole K2 may be beneficial for avoiding the influence on the third connection hole K3 on the display panel, thereby being beneficial for improving the stability and accuracy of signal transmission corresponding to each connection hole.

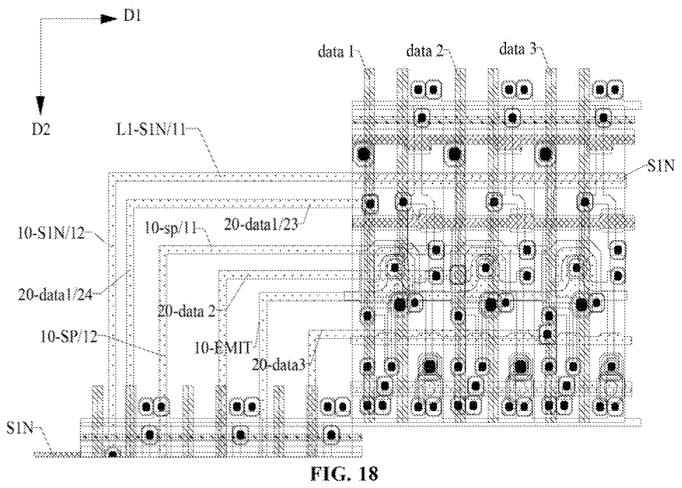

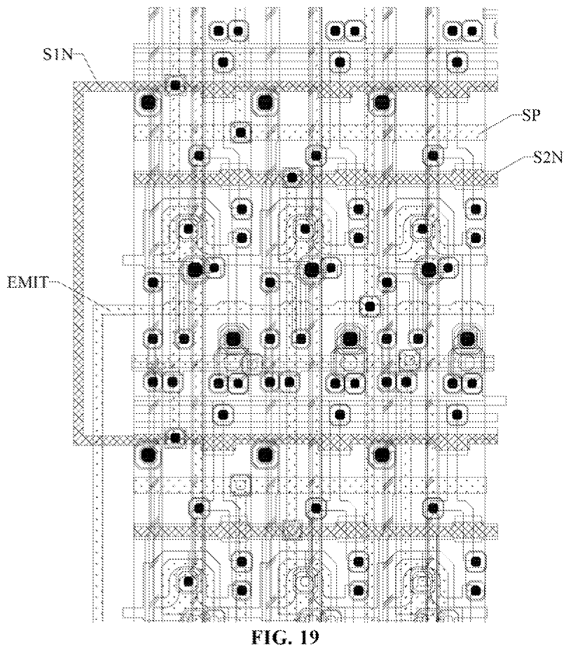

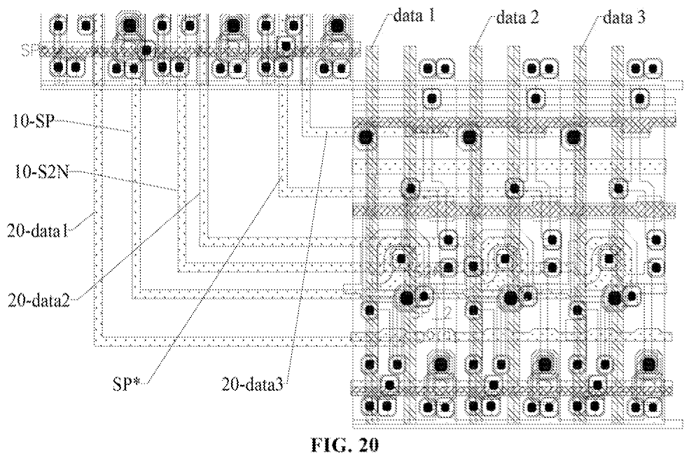

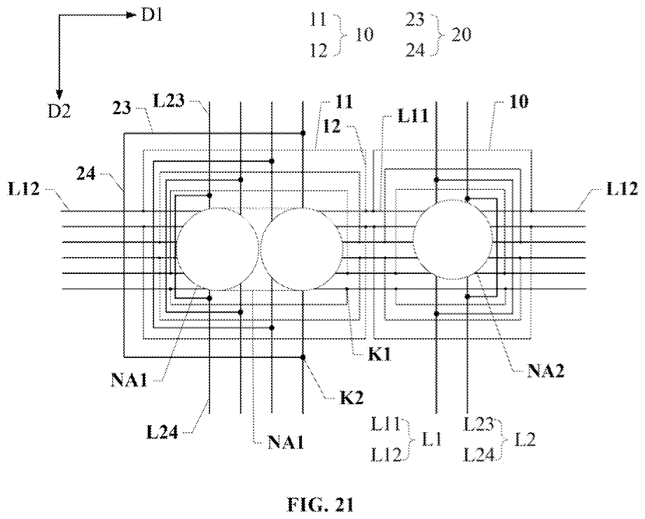

FIG. 18 illustrates a panel layout corresponding to a region A3 in FIG. 17. FIG. 19 illustrates a panel layout corresponding to a region A4 in FIG. 17. FIG. 20 illustrates a panel layout corresponding to a region A5 in FIG. 17. One embodiment illustrates three data lines data1, data2 and data3 that are overlapped with the first non-display region NA1 along the second direction D2 and corresponding part of the second crossing lines 20. The second crossing line 20-data1 represents the second crossing line connected to the data line data1, the second crossing line 20-data2 represents the first crossing line connected to the data line data2, the second crossing line 20-data3 represents the first crossing line connected to the data line data3, the first crossing line 10-SP represents the first crossing line connected to the fourth control line SP, the first crossing line 10-S1N represents the first crossing line connected to the first control line S1N, and the first crossing line 10-EMIT represents the first crossing line connected to the light-emitting control line EMIT.

Referring to FIGS. 17-20, in an optional embodiment of the present disclosure, the second crossing line 20 may include a line segment 24 extending along the second direction D2; and the line segment 24 extending along the second direction D2 may not be overlapped with other second signal lines L2 along the thickness direction of the display panel.

In the display panel provided by embodiments of the present disclosure, the second signal line L2 extending along the second direction D2 may be, for example, a data signal line connected to the pixel drive circuit for providing data signals to the pixel drive circuit, and at least a part of the data lines may not transmit data signals simultaneously. When the line segment extending along the second direction D2 in the second crossing line 20 is overlapped with other second signal lines L2, if the second signal line L2 connected to the second crossing line 20 and the second signal line L2 overlapped with the line segment extending along the second direction D2 in the second crossing line 20 do not transmit data signals simultaneously, or transmitted data signals are different, the signals between such two second signal lines L2 may interfere with each other, which may affect the accuracy and stability of signal transmission. Therefore, in embodiments of the present disclosure, the line segment of the second crossing line 20 extending along the second direction D2 may be configured to not be overlapped with other second signal lines L2 along the thickness direction of the display panel, which may be beneficial for reducing or avoiding signal interference between different second signal lines L2 and improving the accuracy and stability of signal transmission.

In an optional embodiment of the present disclosure, the display panel may include fixed voltage signal lines in the display region AA; the fixed voltage signal lines may include the first fixed voltage signal line extending along the first direction D1 and the second fixed voltage signal line extending along the second direction D2; in the first crossing line 10 and the second crossing line 20, along the thickness direction of the display panel, at least a part of the line segment extending along the first direction D1 may be overlapped with the first fixed voltage signal line, and at least a part of the line segment extending along the second direction D2 may be overlapped with the second fixed voltage signal line.

For example, certain fixed voltage signal lines may be disposed in the display panel, and the voltage on the fixed voltage signal lines may be always constant. Taking the pixel drive circuit shown in FIG. 5 as an example, the signal line connected to the first power supply terminal VDD, the signal line connected to the second power supply terminal VEE, the signal lines connected to the reset signal terminals VREF1 and VREF2, and the signal line connected to the substrate of the storage capacitor Cst receiving a fixed potential and the like may all be fixed voltage signal lines; and the potentials on these signal lines may all be constant. A part of these signal lines may include line segments extending along the first direction D1, and it is assumed that such part of the signal lines is the first fixed voltage signal line. A part of the signal lines may include line segments extending along the second direction D2, and it is assumed that such part of the signal lines is the second fixed voltage signal line. When the first crossing line 10 and the second crossing line 20 are introduced into the display panel, at least a part of the line segments extending along the first direction D1 in two crossing lines is overlapped with the first fixed voltage signal line, and at least a part of the line segments extending along the second direction D2 is overlapped with the second fixed voltage signal line. In such way, the orthographic projections of the first crossing line 10 and the second crossing line 20 in the first signal line L1 on the display panel may be overlapped with the fixed voltage signal line in the display panel. Since the signal on the fixed voltage signal line is constant, it may not cause interference to the signal in the first crossing line 10 and may also improve screen mura phenomenon occurred in the display panel to a certain extent when the first crossing line 10 and the second crossing line 20 are introduced into the display panel.

Optionally, the orthographic projection of the line segments extending along the first direction D1 in the first crossing line 10 and the second crossing line 20 on the display panel may be within the range of the orthographic projection of the first fixed voltage signal line on the display panel; and the orthographic projection of the line segments extending along the second direction D2 in the first crossing line 10 and the second crossing line 20 on the display panel may be within the orthographic projection range of the second fixed voltage signal line on the display panel. In such way, it is equivalent to blocking the first crossing line 10 and the second crossing line 20 by using the fixed voltage signal lines, which may be more beneficial for improving screen mura phenomenon.

Referring to FIG. 18, in an optional embodiment of the present disclosure, in the first crossing line 10 and the second crossing line 20, along the thickness direction of the display panel, at least a part of the line segments 23 extending along the first direction D1 may be overlapped with the first signal line L1. Considering that the display panel is disposed with a plurality of first signal lines L1 extending along the first direction D1, when the first crossing line 10 and the second crossing line 20 are introduced into the display panel, at least a part of the line segments extending along the first direction D1 in the first crossing line 10 and the second crossing line 20 may be overlapped with the first signal line L1, which may be beneficial for simplifying the wiring difficulty of the first crossing line 10 and the second crossing line 20.

Referring to FIG. 17, in an optional embodiment of the present disclosure, the first crossing line 10 may include the first sub-line-segment 11 extending along the first direction D1 and the second sub-line-segment 12 extending along the second direction D2; and the second crossing line 20 may include the third sub-line-segment 23 extending along the first direction D1 and the fourth sub-line-segment 24 extending along the second direction D2; and along the thickness direction of the display panel, the first sub-line-segment 11 may not be overlapped with the third sub-line-segment 23, and the second sub-line-segment 12 may not be overlapped with the fourth sub-line-segment 24.

For example, when the first crossing line 10 is configured to connect the first line segment L11 and the second line segment L12 in the first signal line L1 and when the second crossing line 20 is configured to connect the third line segment L23 and the fourth line segment L24, a same first crossing line 10 may include the first sub-line-segment 11 extending along the first direction D1 and the second sub-line-segment 12 extending along the second direction D2; and a same second crossing line 20 may include the third sub-line-segment 23 extending along the first direction D1 and the fourth sub-line-segment 24 extending along the second direction D2. Optionally, the first sub-line-segment 11 and the third sub-line-segment 23 extending along the first direction D1 may not be overlapped with each other and may no cause short circuit; and the second sub-line-segment 12 and the fourth sub-line-segment 24 extending along the second direction D2 may not be overlapped with each other and may not cause short circuit. In such way, the first sub-line-segment 11 and the second sub-line-segment 12 in the first crossing line 10 and the third sub-line-segment 23 and the fourth sub-line-segment 24 in the second crossing line 20 may be disposed in a same film layer, which may be beneficial for reducing the number of film layers in the display panel and simplifying the film layer structure of the display panel.

Referring to FIG. 17, in an optional embodiment of the present disclosure, at least a part of the third sub-line-segments 23 may be between two adjacent first sub-line-segments 11, and at least a part of the fourth sub-line-segments 24 may be between two adjacent second sub-line-segments 12.

For example, the first sub-line-segments 11 in the first crossing lines 10 and the third sub-line-segments 23 in the second crossing lines 20 may all extend along the first direction D1. When arranging the first sub-line-segments 11 and the third sub-line-segments 23, at least a part of the third sub-line-segments 23 may be arranged between two adjacent first sub-line-segments 11 by an interspersed design manner, which may be beneficial for rationally utilizing the space around the non-display region NA, and avoiding the problem that the wiring range of the first sub-line-segments 11 and the third sub-line-segments 23 may be excessively large when the plurality of first sub-line-segments 11 and the plurality of third sub-line-segments 23 are respectively arranged in two different spaces.

Similarly, the second sub-line-segments 12 in the first crossing lines 10 and the fourth sub-line-segments 24 in the second crossing lines 20 may all extend along the second direction D2. When arranging the second sub-line-segments 12 and the fourth sub-line-segments 24, at least a part of the fourth sub-line-segments 24 may be arranged between two adjacent second sub-line-segments 12 in an interspersed design manner, which may be beneficial for rationally utilizing the space around the non-display region NA and avoiding the problem that the wiring range of the second sub-line-segments 12 and the fourth sub-line-segments 24 may be excessively large when the plurality of second sub-line-segments 12 and the plurality of fourth sub-line-segments 24 are respectively arranged in two different spaces. Therefore, the manner that the first sub-line-segments 11 and the second sub-line-segments 12 are interspersed to be wired and the third sub-line-segments 23 and the fourth sub-line-segments 24 are interspersed to be wired may be beneficial for simplifying the wiring range of the first crossing lines 10 and the second crossing lines 20 on the display panel scope. When the number of the first crossing lines 10 and the second crossing lines 20 is large, it is beneficial for avoiding the problem of insufficient wiring space on the display panel, thereby being beneficial for ensuring the narrow frame design around the first non-display region NA1 and the second non-display region NA2.

FIG. 21 illustrates a wiring schematic of first signal lines L1 and second signal lines L2 disposed by surrounding the first non-display region NA1 and the second non-display region NA2. In an optional embodiment of the present disclosure, along the first direction D1, the length of the first non-display region NA1 may be greater than the length of the second non-display region NA2; and at least a part of the second crossing lines 20 may half surrounds the first crossing lines 10 on the side of the first non-display region NA1 away from the second non-display region NA2.

Referring to FIG. 21, when the first non-display region NA1 and the second non-display region NA2 are introduced into the display panel, optionally, the size of the first non-display region NA1 and the second non-display region NA2 along the first direction D1 may be different. For example, the width of the first non-display region NA1 along the first direction D1 may be greater than the width of the second non-display region NA2 along the second direction D2. Optionally, the first non-display region NA1 may include two light-transmitting holes, and the second non-display region NA2 includes a single light-transmitting hole. At this point, the number of the second signal lines L2 overlapped with the first non-display region along the second direction D2 may be greater than the number of the second signal lines L2 overlapped with the second non-display region NA2 along the second direction D2. In such way, the number of the second crossing lines 20 corresponding to the first non-display region NA1 may be greater than the number of the second crossing lines 20 corresponding to the second non-display region NA2. When at least a part of the line segments in the first crossing line 10 and the second crossing line 20 are designed with an interspersed manner, due to large number of the second crossing lines 20, a part of the second crossing lines 20 may not be interspersed. At this point, such part of the second crossing lines 20 may be arranged on the side of the first non-display region NA1 away from the second non-display region NA2 and may be designed to half surround the first crossing line 10, so that the space of the first non-display region NA1 and the second non-display region NA2 may be reasonably utilized. It should be noted that, since the size of the second non-display region along the first direction D1 is relatively small, the first crossing lines 10 and the second crossing lines 20 corresponding to the second non-display region NA2 may be wired using an interspersed manner. If the number of the second crossing lines 20 corresponding to the second non-display region NA2 is greater than the number of the first crossing lines 10, a part of the second crossing lines 20 may be wired on the side of the second non-display region NA2 away from the first non-display region NA1 and in a manner of at least partially including the first crossing lines 10, which may not be limited in the present disclosure.

Referring to FIGS. 10, 16 and 17, in an optional embodiment of the present disclosure, the display panel may include a substrate 00 and a transistor layer disposed on the substrate, and the transistor layer may include the first type transistor M01 and the second type transistor M02. The display panel may include the first metal layer M1, the second metal layer M2, the gate metal layer MG, the capacitor metal layer MC, the third metal layer M3 and the fourth metal layer M4. The gate electrode of the first type transistor M01 may be in the first metal layer M1, the gate electrode of the second type transistor M02 may be in the gate metal layer MG, and the source and drain electrodes of the first type transistor M01 and the second type transistor M02 may be in the second metal layer M2. The capacitor metal layer MC may be between the first metal layer M1 and the second metal layer M2, the third metal layer M3 may be on the side of the second metal layer M2 away from the substrate, and the fourth metal layer M4 may be on the side of the third metal layer M3 away from the substrate. At least a part of the line segments in the first crossing line 10 may be in the fourth metal layer M4.

For example, the display panel in one embodiment shown in FIG. 10 may include two types of transistors. Optionally, the first type transistor M01 may be a low temperature polysilicon transistor, the second type transistor M02 may be an oxide transistor. Referring to FIG. 5, the drive transistor M0, the first transistor M1 in the data write module 61, the fourth transistor M4 in the data write module 61, the fourth transistor M4 and the fifth transistor M5 in the light-emitting control module 65, the second reset module 64 in the sixth transistor M6, and the seventh transistor M7 in the voltage adjustment module 66 may all be first type transistors M01; and the second transistor M2 in the compensation module 62 and the third transistor M3 in the first reset module 63 may both be second type transistors M02. Since both the second transistor M2 and the third transistor M3 are transistors directly connected to the first node N1, the leakage current of the second transistor M2 and the third transistor M3 may directly affect the potential of the first node N1. When the second transistor M2 and the third transistor M3 are configured as oxide transistors, since the leakage current of the oxide transistor is relatively small, it is beneficial for avoiding or reducing the influence of the leakage current of the second transistor M2 and the third transistor M3 on the potential of the first node N1, thereby being beneficial for improving the light-emitting stability of the light-emitting element.

Referring to FIGS. 3, 5, 10, 16, and 17, optionally, in embodiments of the present disclosure SP, the first control line S1N, the second control line S2N, the third control line SP*, the fourth control line and the light-emitting control line EMIT may be in any film layer in the first metal layer M1, the capacitor metal layer MC, the gate metal layer MG, and the third metal layer M3; and the first line segment L11 and the second line segment L12 in a same control line may be in a same metal layer or different metal layers, which may not be limited in the present disclosure. For example, the first control line S1N and the second control line S2N may be disposed in the gate metal layer MG; and the third control line SP*, the light-emitting control line EMIT, and the fourth control line SP may be disposed in the first metal layer, which may be merely exemplary. In some other embodiments of the present disclosure, the film layers that the first control line S1N, the second control line S2N, the third control line SP*, the fourth control line SP and the light-emitting control line EMIT are actually located may be adjusted according to actual needs.

In one embodiment, at least a part of the line segments in the first crossing lines 10 connecting the first line segments L11 and the second line segments L12 may be disposed in the fourth metal layer M4. Optionally, the first crossing lines 10 may all be disposed on the fourth metal layer M4. Since the first line segment L11 and the second line segment L12 in the first crossing line 10 and the first signal line L1 are both arranged in different layers, the manner that the first crossing line 10 is configured to connect the first line segment L11 and the second line segment L12 may avoid the problem that the first line segment L11 and the second line segment L12 are wired around the non-display region NA to cause the frame width around the non-display region NA to be excessively large, which may be beneficial for reducing the narrow frame design around the non-display region NA.

It should be noted that, referring to FIGS. 16 and 17, when the second crossing line 20 is introduced into the display panel to realize the electrical connection between the third line segment L23 and the fourth line segment L24 in the second signal line L2, optionally, the third line segment L23 and the fourth line segment L24 in the second signal line L2 may be disposed in the second metal layer M2 or the third metal layer M3, and also be disposed on other film layers that do not interfere with the first signal line L1, which may not be limited in the present disclosure. At this point, both the second crossing line 20 and the first crossing line 10 may be disposed in the fourth metal layer M4. Therefore, it is no need to introduce two different film layers into the display panel to dispose the first crossing line 10 and the second crossing line 20 respectively, which may be beneficial for simplifying the film layer complexity of the display panel.

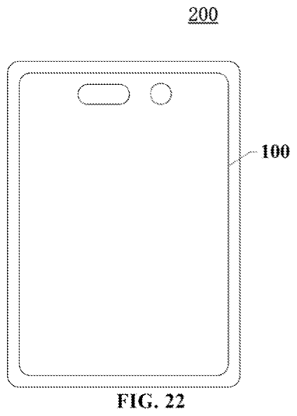

Based on the same inventive concept, the present disclosure also provides a display apparatus. FIG. 22 illustrates a structural schematic of a display apparatus according to various embodiments of the present disclosure. A display apparatus 200 provided in one embodiment may include the display panel 100 provided by any of above-mentioned embodiments of the present disclosure.

It can be understood that the display apparatus 200 provided in embodiments of the present disclosure may be a computer, a mobile phone, a tablet, or other display apparatus having a display function, which may not be limited by the present disclosure. The display apparatus provided by embodiments of the present disclosure may have the beneficial effects of the display panel provided by embodiments of the present disclosure, which may refer to the specific descriptions of the display panels in above embodiments and may not be described in detail in one embodiment.

From above-mentioned embodiments, it may be seen that the display panel and the display apparatus provided by the present disclosure may achieve at least following beneficial effects.

The display panel provided by embodiments of the present disclosure may be disposed with at least two non-display regions, and the display region may at least partially surround above-mentioned non-display regions. The non-display regions may at least include the first non-display region and the second non-display region which are arranged along the first direction. The display region may include the plurality of first signal lines extending along the first direction. Along the first direction, a part of the first signal lines may be overlapped with the first non-display region and the second non-display region. Such part of the first signal lines may include the first line segment and at least one second line segment. The first line segment may be between two adjacent non-display regions, and at least a part of the second line segments may be on the side of the first non-display region away from the second non-display region, and/or at least a part of the second line segments may be on the side of the second non-display region away from the first non-display region. In order to realize the electrical connection between the first line segment and the second line segment in the first signal line, the present disclosure introduces the first crossing line into the display panel. The first crossing line may be disposed at different layers from the first line segment and the second line segment in the first signal line. When the first line segments and the second line segments are connected through the first crossing lines, there is no need to wire the first non-display region or the frame region of the second non-display region, which may reduce the number of wirings corresponding to the frame regions of the first non-display region and the second non-display region and provide compression space for the frames of the first non-display region and the second non-display region, thereby be beneficial for realizing the narrow frame corresponding to the first non-display region and the second non-display region and increasing the screen-to-body ratio of the display panel and the display apparatus.

Although some embodiments of the present disclosure have been described in detail through examples, those skilled in the art should understand that above-mentioned examples are provided for illustration only and not for the purpose of limiting the scope of the disclosure. Those skilled in the art should understand that modifications may be made to above-mentioned embodiments without departing from the scope and spirit of the present disclosure. The scope of the present disclosure may be defined by appended claims.

What is claimed is:

1. A display panel, comprising:
a display region and at least two non-display regions, wherein:
the at least two non-display regions at least include a first non-display region and a second non-display region which are disposed to be adjacent to each other; the first non-display region and the second non-display region are arranged along a first direction; and the display region at least partially surrounds the at least two non-display regions; and
the display region includes a plurality of first signal lines extending along the first direction; at least a part of the plurality of first signal lines includes at least one first line segment and at least one second line segment; the at least one first line segment is between two adjacent non-display regions; at least a part of the at least one second line segment is on a side of the first non-display region away from the second non-display region along the first direction, and/or, at least a part of the at least one second line segment is on a side of the second non-display region away from the first non-display region along the first direction; and in a same first signal line, a first line segment of the at least one first line segment and a second line segment of the at least one second line segment are electrically connected with each other through a first crossing line.

2. The display panel according to claim 1, further including:
a plurality of pixel drive circuits in the display region and a plurality of light-emitting elements electrically connected to the plurality of pixel drive circuits, wherein the plurality of pixel drive circuit is electrically connected to a plurality of control lines, and the plurality of first signal lines includes the plurality of control lines; and
a first frame region and a second frame region which are opposite to each other along the first direction, wherein both the first frame region and the second frame region include a plurality of shift registers; at least a part of the plurality of control lines is electrically connected to the plurality of shift registers in the first frame region, and at least a part of the plurality of control lines is electrically connected to the plurality of shift registers in the second frame region; first crossing lines corresponding to at least a part of the plurality of control lines are wired along a first side of a second direction with respect to the first non-display region and the second non-display region; and first crossing lines corresponding to at least a part of the plurality of control lines are wired along a second side of the second direction with respect to the first non-display region and the second non-display region; the first side and the second side are opposite to each other along the second direction; and the second direction intersects the first direction.

3. The display panel according to claim 2, wherein:
a quantity of first crossing lines wired along the first side of the second direction with respect to the first non-display region and the second non-display region is same as a quantity of first crossing lines wired along the second side of the second direction with respect to the first non-display region and the second non-display region.

4. The display panel according to claim 2, wherein:
a pixel drive circuit of the plurality of pixel drive circuits includes a data write module, a compensation module, a first reset module, a second reset module, a light-emitting control module and a voltage adjustment module; the plurality of control lines includes a first control line connected to a control terminal of the first reset module, a second control line connected to a control terminal of the compensation module, a third control line connected to control terminals of the second reset module and the voltage adjustment module, a fourth control line connected to a control terminal of the data write module, and a light-emitting control line connected to the light-emitting control module; and
two of the first control line, the second control line, the third control line and the light-emitting control line are connected to shift registers in the first frame region; and the other two of the first control line, the second control line, the third control line and the light-emitting control line are connected to shift registers in the second frame region.

5. The display panel according to claim 4, wherein:
at least a part of fourth control lines connecting to first crossing lines is connected to the shift registers in the first frame region; and a remaining part of fourth control lines connecting to first crossing lines is connected to the shift registers in the second frame region.

6. The display panel according to claim 4, further including:
a plurality of pixel rows, wherein each pixel row includes a plurality of light-emitting elements; at least one of the first control line, the second control line, the third control line and the light-emitting control line is electrically connected to pixel drive circuits corresponding to light-emitting elements in N pixel rows respectively, wherein N2; and the fourth control line is only electrically connected to pixel drive circuits corresponding to light-emitting elements in a same pixel row.

7. The display panel according to claim 6, wherein:
the first line segment includes a first terminal adjacent to the first non-display region and a second terminal adjacent to the second non-display region; and
at least one of the first control line, the second control line, the third control line, and the light-emitting control line in adjacent N pixel rows is electrically connected to first or second terminals of N corresponding first line segments.

8. The display panel according to claim 4, wherein:
at least one of the first reset module and the compensation module includes a metal oxide transistor; between the first non-display region and the second non-display region, along a thickness direction of the display panel, the metal oxide transistor includes an active layer, and a first gate electrode and a second gate electrode which are respectively on two sides of the active layer; and in a same metal oxide transistor, terminals of the first gate electrode and the second gate electrode are electrically connected with each other.

9. The display panel according to claim 4, wherein:
the first control line, the second control line, the third control line, the fourth control line and the light-emitting control line are distributed in at least two different film layers.

10. The display panel according to claim 4, wherein:
first crossing lines corresponding to the first control line, the second control line, the third control line and the light-emitting control line respectively include a first sub-first-crossing-line and a second sub-first-crossing-line; and a first end of a first line segment in the first control line, the second control line, the third control line and the light-emitting control line is connected to a second line segment on a side of the first non-display region away from the second non-display along the first direction through the first sub-first-crossing-line, and a second end of the first line segment is connected to a second line segment on a side of the second display region away from the first non-display region along the first direction through the second sub-first-crossing-line.

11. The display panel according to claim 10, wherein:
at least three pixel columns are arranged between the first non-display region and the second non-display region; the first line segment is electrically connected to the first sub-first-crossing-line through a first via and to the second sub-first-crossing-line through a second via; and along the first direction, a distance between the first via and the second via is greater than or equal to a total width of three consecutive pixel columns.

12. The display panel according to claim 4, wherein:
a first line segment in the fourth control line is electrically connected to a second line segment on a side of the first line segment along the first direction through a first crossing line.

13. The display panel according to claim 4, wherein:
in first crossing lines connected to fourth control lines, at least a part of the first crossing lines is at the first side of the second direction with respect to the first line segment, and at least a part of the first crossing lines is at the second side of the second direction with respect to the first line segment; and
in first crossing lines connected to at least one of the first control line, the second control line, the third control line and the light-emitting control line, at least a part of the first crossing lines is on at least one side of the first line segment along the second direction.

14. The display panel according to claim 13, wherein:
at least three pixel columns are arranged between the first non-display region and the second non-display region; in first crossing lines, which are between the first non-display region and the second non-display region and correspond to the first control line, the second control line, the third control line, the fourth control line and the light-emitting control line, line segments extending along the second direction are within a range defined by three consecutive pixel columns.

15. The display panel according to claim 1, further including:
a frame region configured by at least partially surrounding the display region, wherein at least a part of line segments in first crossing lines is at the frame region.

16. The display panel according to claim 1, wherein:
the display region further includes a plurality of second signal lines extending along a second direction; at least a part of the plurality of second signal lines includes a third line segment and a fourth line segment which are arranged along the second direction; along the second direction, the third line segment and the fourth line segment are on two sides of the first non-display region or on two sides of the second non-display region; in a same second signal line, the third line segment and the fourth line segment are electrically connected with each other through a second crossing line; at least a part of second crossing lines is disposed at a same layer as first crossing lines; and the second direction intersects the first direction.

17. The display panel according to claim 16, wherein:
the second crossing lines are disposed at a same layer as the first crossing lines.

18. The display panel according to claim 16, wherein:
the first crossing line is connected to a first signal line of the plurality of first signal lines through a first connection hole, and the second crossing line is electrically connected to a second signal line of the plurality of second signal lines through a second connection hole; the display panel further includes a plurality of third connection holes; and along a thickness direction of the display panel, the first connection hole, the second connection hole, and a third connection hole of the plurality of third connection holes are not overlapped with each other.

19. The display panel according to claim 16, wherein:
the second crossing line includes a line segment extending along the second direction; and the line segment extending along the second direction is not overlapped with other second signal lines along a thickness direction of the display panel.

20. The display panel according to claim 16, further including:
fixed voltage signal lines in the display region, wherein the fixed voltage signal lines include a first fixed voltage signal line extending along the first direction and a second fixed voltage signal line extending along the second direction; in the first crossing line and the second crossing line, along a thickness direction of the display panel, at least a part of line segments extending along the first direction is overlapped with the first fixed voltage signal line, and at least a part of line segments extending along the second direction is overlapped with the second fixed voltage signal line.

21. The display panel according to claim 16, wherein:
in the first crossing line and the second crossing line, along a thickness direction of the display panel, at least a part of line segments extending along the first direction is overlapped with the first signal line.

22. The display panel according to claim 16, wherein:
the first crossing line includes a first sub-line-segment extending along the first direction and a second sub-line-segment extending along the second direction; the second crossing line includes a third sub-line-segment extending along the first direction and a fourth sub-line-segment extending along the second direction; and along a thickness direction of the display panel, the first sub-line-segment and the third sub-line-segment are not overlapped with each other, and the second sub-line-segment and the fourth sub-line-segment are not overlapped with each other.

23. The display panel according to claim 22, wherein:
at least a part of the third sub-line-segment is between two adjacent first sub-line-segments, and at least a part of the fourth sub-line-segment is between two adjacent second sub-line-segments.

24. The display panel according to claim 16, wherein:
along the first direction, a length of the first non-display region is greater than a length of the second non-display region; and at least a part of second crossing lines half surrounds the first crossing line on a side of the first non-display region away from the second non-display region.

25. The display panel according to claim 1, further including:
a substrate and a transistor layer disposed on the substrate, wherein the transistor layer includes a first type transistor and a second type transistor;
a first metal layer, a second metal layer, a gate metal layer, a capacitor metal layer, a third metal layer and a fourth metal layer, wherein a gate electrode of the first type transistor is in the first metal layer, a gate electrode of the second type transistor is in the gate metal layer, and source and drain electrodes of the first type transistor and the second type transistor are in the second metal layer; the capacitor metal layer is between the first metal layer and the second metal layer; the third metal layer is on a side of the second metal layer away from the substrate; and the fourth metal layer is on a side of the third metal layer away from the substrate; and
at least a part of line segments in first crossing lines is in the fourth metal layer.

26. A display apparatus, comprising:
a display panel, comprising:
a display region and at least two non-display regions, wherein:
the at least two non-display regions at least include a first non-display region and a second non-display region which are disposed to be adjacent to each other; the first non-display region and the second non-display region are arranged along a first direction; and the display region at least partially surrounds the at least two non-display regions; and
the display region includes a plurality of first signal lines extending along the first direction; at least a part of the plurality of first signal lines includes at least one first line segment and at least one second line segment; the at least one first line segment is between two adjacent non-display regions; at least a part of the at least one second line segment is on a side of the first non-display region away from the second non-display region along the first direction, and/or, at least a part of the at least one second line segment is on a side of the second non-display region away from the first non-display region along the first direction; and in a same first signal line, a first line segment of the at least one first line segment and a second line segment of the at least one second line segment are electrically connected with each other through a first crossing line.
